(19) United States
(12) Patent Application Publication
(10) Pub. No.: US 2024/0179988 A1
(43) Pub. Date: May 30, 2024

(54) DISPLAY DEVICE AND METHOD FOR MANUFACTURING THE SAME

(71) Applicant: Samsung Display Co., LTD., Yongin-si (KR)

(72) Inventor: KYONGTAE YU, Yongin-si (KR)

(21) Appl. No.: 18/506,490

(22) Filed: Nov. 10, 2023

(30) Foreign Application Priority Data
Nov. 28, 2022 (KR) 10-2022-0161789

(51) Int. Cl. H10K 59/35; H10K 50/115; H10K 50/15; H10K 50/16; H10K 50/17; H10K 59/12; H10K 59/122; H10K 71/13; H10K 71/60

(52) U.S. Cl. CPC H10K 59/35; H10K 50/115; H10K 50/15; H10K 50/166; H10K 50/171; H10K 59/1201; H10K 59/122; H10K 71/135; H10K 71/60

(57) ABSTRACT

Provided are a display device and a method for manufacturing the same. The display device includes a first base substrate on which a first pixel area, a second pixel area, and a third pixel area are defined and a display element layer on the first base substrate and including first to third light emitting elements to respectively correspond to the first to third pixel areas. Each of the first to third light emitting elements includes a first electrode, a first layer on the first electrode, a first inorganic layer on the first layer, an emission layer on the first inorganic layer, a second layer on the emission layer, and a second electrode on the second layer. One selected from the first layer and the second layer includes a hole transport region, and the other includes an electron transport region.

### CROSS-REFERENCE TO RELATED APPLICATION

This application claims priority to and the benefit of Korean Patent Application No. 10-2022-0161789, filed on Nov. 28, 2022, the entire contents of which are hereby incorporated by reference.

### BACKGROUND

### 1. Field

Embodiments of the present disclosure herein relate to a display device and a method for manufacturing the same, and, for example, to a display device having improved lifespan characteristics and luminous efficiency, and a method for manufacturing the same.

### 2. Description of the Related Art

Various display devices used in multimedia equipment such as televisions, mobile phones, table computers, navigation devices, and game consoles are being developed. In some display devices, a so-called self-luminous display element is used that realizes a display by emitting light from a light emitting material containing an organic compound.

In addition, to improve the color reproducibility of the display device, development of a light emitting element using quantum dots as the light emitting material is in progress, and it is required or desired to improve brightness and lifespan of the light emitting element using the quantum dots.

### SUMMARY

Embodiments of the present disclosure provide a display device including a light emitting element having improved brightness and lifespan of the light emitting element.

Embodiments of the present disclosure also provide a method for manufacturing a display device.

An embodiment of the present disclosure provides a display device including: a first base substrate on which a first pixel area configured to emit a first color light, a second pixel area configured to emit a second color light different from the first color light, and a third pixel area configured to emit a third color light different from the first color light and the second color light are defined; and a display element layer on the first base substrate and comprising first to third light emitting elements to respectively correspond to the first to third pixel areas, wherein each of the first to third light emitting elements includes: a first electrode; a first layer on the first electrode; a first inorganic layer on the first layer; an emission layer on the first inorganic layer; a second layer on the emission layer; and a second electrode on the second layer, wherein one selected from the first layer and the second layer is a hole transport region, and the other is an electron transport region.

In an embodiment of the present disclosure, a method for manufacturing a display device includes: providing a preliminary substrate on which a first electrode and a pixel defining layer that exposes a portion of the first electrode are provided; preparing a master substrate on which a transfer pattern patterned to correspond to the pixel defining layer is provided; transferring the transfer pattern onto the pixel defining layer; forming a first layer on the exposed first electrode; depositing a first inorganic layer on the first layer; removing the transfer pattern; forming an emission layer on the first inorganic layer by an inkjet printing method; forming a second layer on the emission layer; and forming a second electrode on the second layer, wherein the forming of the first layer includes forming a deposition layer made of a hole transport material or an electron transport material.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view of a display device according to an embodiment of the present disclosure;

FIG. 2 is a cross-sectional view of the display device according to an embodiment of the present disclosure;

FIG. 3 is an enlarged plan view illustrating a portion of the display device according to an embodiment of the present disclosure;

FIGS. 4A-4B are enlarged cross-sectional views illustrating a portion of the display device according to an embodiment of the present disclosure;

FIGS. 5A-5D and 6A-6D are schematic cross-sectional views illustrating a light emitting element according to an embodiment of the present disclosure; and

FIGS. 7A-7J and 8A-8B are cross-sectional views for explaining a method for manufacturing a display device according to an embodiment of the present disclosure.

### DETAILED DESCRIPTION

Because the subject matter of the present disclosure may have diverse modified embodiments, example embodiments are illustrated in the drawings and are described in the detailed description of the present disclosure. However, this does not limit the present disclosure within the disclosed example embodiments and it should be understood that the present disclosure covers all the modifications, equivalents, and replacements within the idea and technical scope of the present disclosure.

In this specification, it will also be understood that when one component (or area, layer, portion) is referred to as being ‘on’, ‘connected to’, or ‘coupled to’ another component, it can be directly connected/coupled on/to the one component, or an intervening third component may also be present.

In this specification, “directly on,” “directly connected to,” and “directly coupled to” may mean that there is no layer, film, area, plate, or the like between a portion of the layer, the layer, the area, the plate, and/or the like and the other portion. For example, “directly on,” “directly connected to,” and “directly coupled to” may mean being provided without using an additional member such and an adhesion member between two layers or two members.

Like reference numerals refer to like elements throughout. Also, in the figures, the thickness, ratio, and dimensions of components may be exaggerated for clarity of illustration. The term “and/or” includes any and all combinations of one or more of the associated elements.

It will be understood that although the terms such as ‘first’ and ‘second’ are used herein to describe various elements, these elements should not be limited by these terms. These terms are used only to distinguish one component from other components. For example, a first element referred to as a first element in an embodiment can be referred to as a second element in another embodiment without departing from the scope of the appended claims, and equivalents thereof. The terms of a singular form may include plural forms unless referred to the contrary.

Also, “under”, “below”, “above', “upper”, and the like are used for explaining relative association of the elements illustrated in the drawings. The terms may be a relative concept and described based on directions expressed in the drawings. In this specification, the term “on” may refer to a case in which it is on a lower portion as well as an upper portion of any one member.

The meaning of ‘include’ or ‘comprise’ specifies a property, a fixed number, a process, an operation, an element, a component or a combination thereof, but does not exclude other properties, fixed numbers, processes, operations, elements, components or combinations thereof.

Unless otherwise defined, all terms (including technical and scientific terms) used herein have the same meaning as commonly understood by a person of ordinary skill in the art to which this disclosure belongs. In addition, terms such as terms defined in commonly used dictionaries should be interpreted as having a meaning consistent with the meaning in the context of the related technology, and unless explicitly defined here, should not be interpreted in a manner that is too ideal or too formal.

Hereinafter, a display device and a method for manufacturing the same according to an embodiment of the present disclosure will be described with reference to the accompanying drawings.

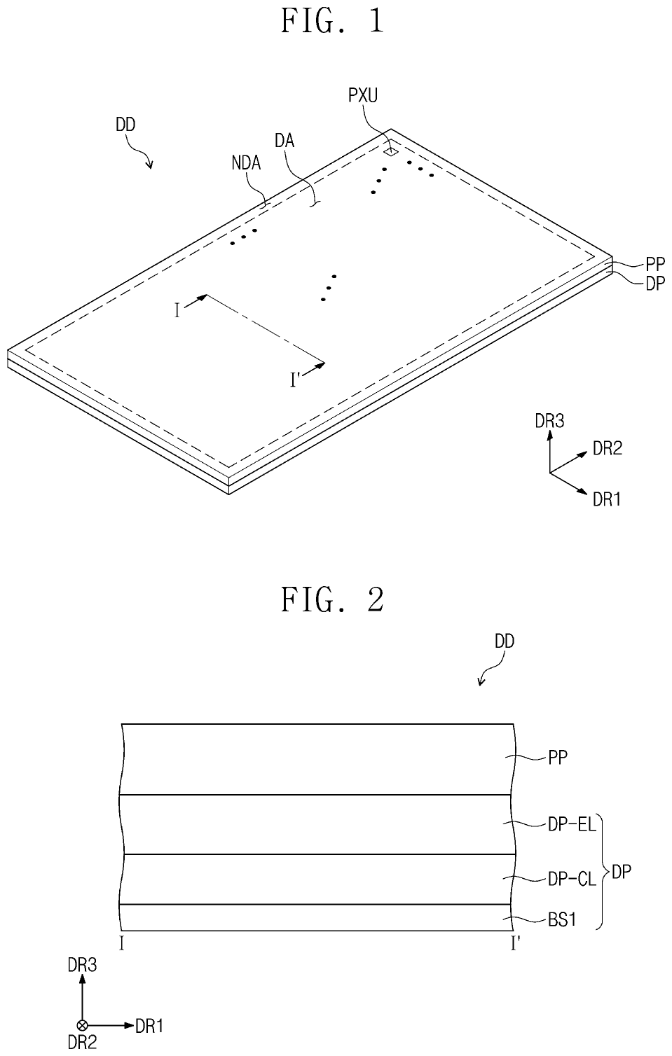

FIG. 1 is a perspective view of a display device according to an embodiment of the present disclosure. FIG. 2 is a cross-sectional view of the display device according to an embodiment of the present disclosure. FIG. 2 is a schematic cross-sectional view illustrating a portion corresponding to a line I-I′ of FIG. 1.

A display device DD according to an embodiment may be a device that is activated according to an electrical signal. The display device DD may include various embodiments. For example, the display device DD may be a large display device such as a television, a monitor, or an external billboard. Also, the display device DD may be used for small or medium-sized display devices such as personal computers, notebook computers, personal digital assistants, car navigation units, game consoles, smart phones, tablet PCs, and cameras. Also, the above-described devices are merely provided as example embodiments, and thus, the display device DD may be adopted for other devices unless it departs from the spirit and scope of the present disclosure.

In FIG. 1 and following figures, first to third directional axes DR1 to DR3 are illustrated, and directions indicated by the first to third directional axes DR1, DR2, and DR3, which are described in this specification, may be relative concepts and thus may be changed into different directions. Also, directions indicated by the first to third direction axes DR1, DR2, and DR3 may be described as first to third directions, and the same reference numerals may be used.

A thickness direction of the display device DD may be a direction parallel (or substantially parallel) to the third directional axis DR3, which is a normal direction to the plane defined by the first directional axis DR1 and the second directional axis DR2. In this specification, a front surface (or top surface) and a rear surface (or bottom surface) of each of members constituting the display device DD may be defined based on the third directional axis DR3. In this specification, the term “on the plane” may be defined as a state when viewed in the third directional axis DR3. In this specification, “on the cross-section” may be defined as a state when viewed from the first directional axis DR1 or the second directional axis DR2.

Referring to FIG. 1, the display device DD according to an embodiment may include a display area DA and a non-display area NDA adjacent to the display area DA. The display area DA may be an area on which an image is displayed. The non-display area NDA may be an area on which an image is not displayed (or is not designed to be displayed). In an embodiment, unit pixels PXU may be on the display area DA, and the unit pixels PXU may not be on the non-display area NDA. A plurality of lines and driving circuits for driving the unit pixels PXU may be on the non-display area NDA.

The unit pixels PXU illustrated in FIG. 1 may define a pixel row and a pixel column. The unit pixel PXU may include at least one pixel as a minimum repetition unit. The unit pixel PXU may include a plurality of pixels providing light having colors different from each other.

In an embodiment, the display area DA may have a rectangular shape. The non-display area NDA may surround the display area DA. However, the embodiment of the present disclosure is not limited thereto. For example, the display area DA and the non-display area NDA may be relatively designed in shape. In some embodiments, the non-display area NDA may not exist on a display surface that is the front surface of the display device DD.

Referring to FIG. 2, the display device DD according to an embodiment may include a display panel DP and an optical member PP.

In an embodiment, the display panel DP may be an emission type (or kind) of display panel. For example, the display panel DP may be an organic light emitting display panel, an inorganic light emitting display panel, and/or a quantum dot light emitting display panel. An emission layer of the organic light emitting display panel may include an organic light emitting material, and an emission layer of the inorganic light emitting display panel may include an inorganic light emitting material. An emission layer of the quantum dot light emitting display panel may include a quantum dot, a quantum rod, and/or the like. Hereinafter, the display panel DP is described as an organic light emitting display panel.

The display panel DP may include a first base substrate BS1, a circuit layer DP-CL, and a display element layer DP-EL.

The first base substrate BS1 may be a member providing a base surface on which the circuit layer DP-CL and the display element layer DP-EL are provided. The first base substrate BS may include a single layer or multiple layers. For example, the first base substrate BS may include a three-layer structure of a polymer resin layer, an adhesive layer, and a polymer resin layer. For example, the polymer resin layer may include a polyimide-based resin. In some embodiments, the polymer resin layer may include at least one selected from an acrylate-based resin, a methacrylate-based resin, a polyisoprene-based resin, a vinyl-based resin, an epoxy-based resin, an urethane-based resin, a cellulose-based resin, a siloxane-based resin, a polyamide-based resin, and a perylene-based resin. In this specification, a polyimide-based resin means one containing a functional group of polyimide. In addition, a corresponding explanation may be applied to the acrylate-based resin, the methacrylate-based resin, the polyisoprene-based resin, the vinyl-based resin, the epoxy-based resin, the urethane-based resin, the cellulose-based resin, the siloxane-based resin, the polyamide-based resin, and the perylene-based resin. In addition, the first base substrate BS1 may include a glass substrate, a metal substrate, and/or an organic/inorganic composite substrate. The first base substrate BS1 may be a flexible substrate that is capable of being easily bent and/or folded.

The circuit layer DP-CL may be on the first base substrate BS1, and the circuit layer DP-CL may include a plurality of transistors. The circuit layer DP-CL may include an insulating layer, a semiconductor pattern, a conductive pattern, and a signal line. For example, the circuit layer DP-CL may include a switching transistor and a driving transistor for driving the light emitting element of the display element layer DP-EL.

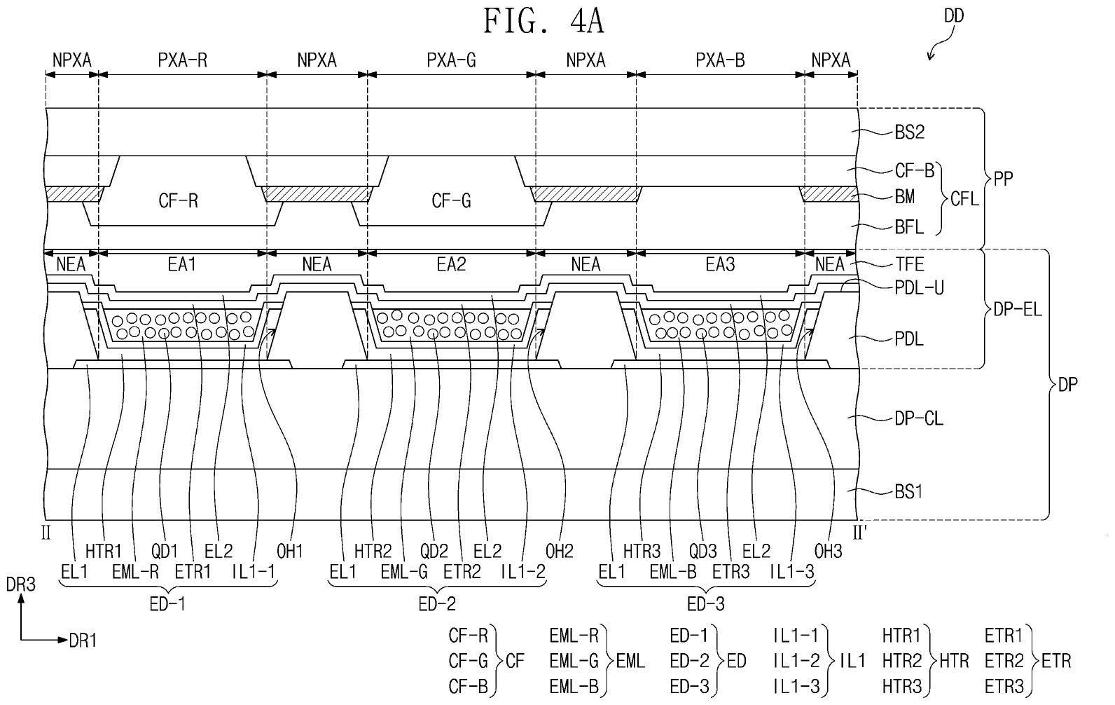

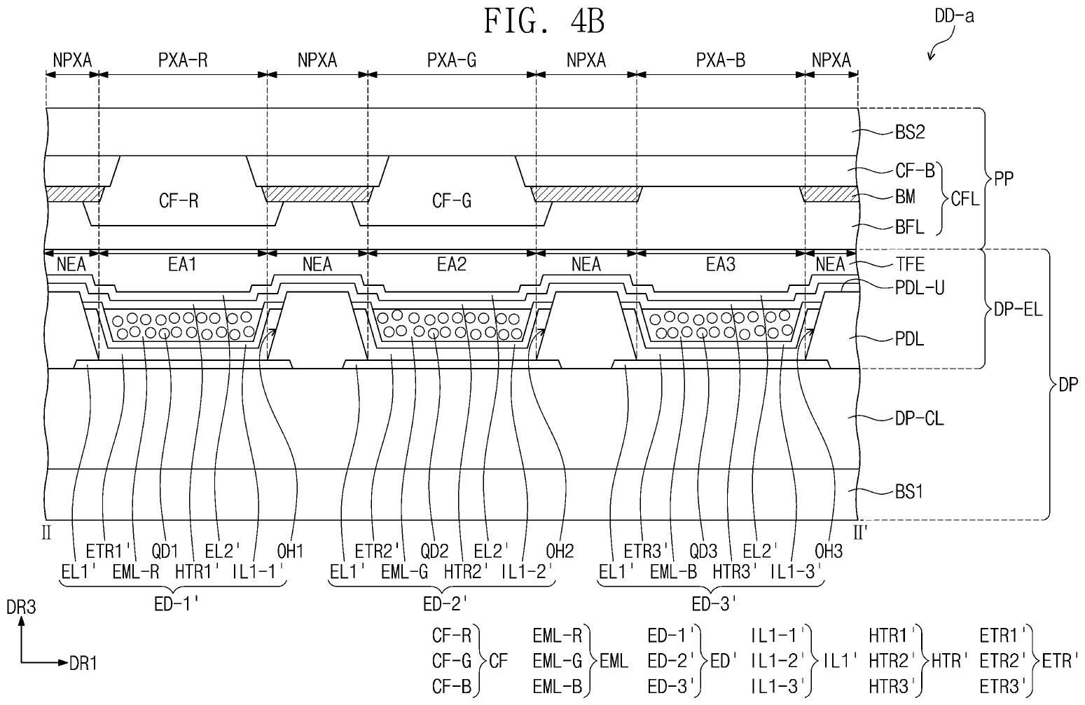

The display element layer DP-EL may be on the circuit layer DP-CL, and the display element layer DP-EL may include a plurality of light emitting elements ED-1, ED-2, and ED-3 (see FIG. 4A). A detailed description of the display element layer DP-EL will be further described herein below.

The optical member PP may be on the display panel DP to control light reflected from the display panel DP by external light. For example, the optical member PP may include a color filter layer or a polarization layer. However, according to another embodiment of the present disclosure, the optical member PP may be omitted.

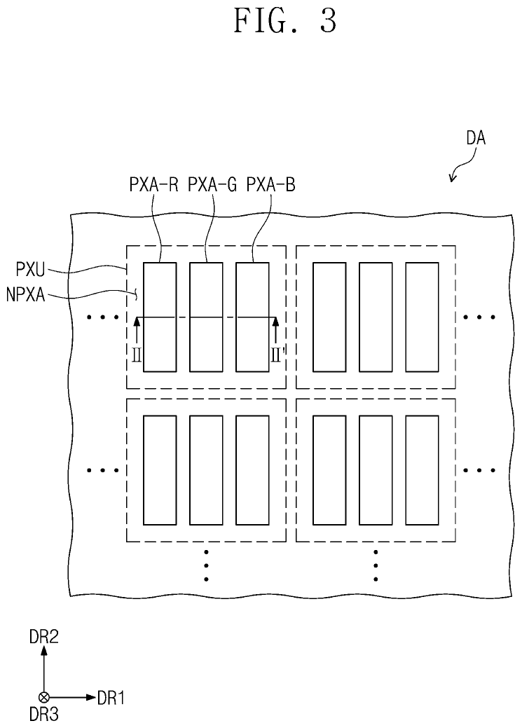

FIG. 3 is an enlarged plan view illustrating a portion of the display device according to an embodiment of the present disclosure. FIG. 3 illustrates an enlarged view of a portion of an display area of the display device according to an embodiment. FIGS. 4A-4B are enlarged cross-sectional views illustrating a portion of the display device according to an embodiment of the present disclosure. FIGS. 4A-4B illustrate a portion corresponding to a II-II′ of FIG. 3.

As illustrated in FIG. 3, the unit pixels PXU may be arranged in a first direction DR1 and a second direction DR2, respectively. In one embodiment, the unit pixel PXU may include a first pixel, a second pixel, and a third pixel, which emit light having colors different from each other. The first pixel, the second pixel, and the third pixel may output red light, green light, and blue light, respectively. FIG. 3 illustrates a first pixel area PXA-R, a second pixel area PXA-G, and a third pixel area PXA-B, which represent the first pixel, the second pixel, and the third pixel, respectively.

The first to third pixel areas PXA-R, PXA-G, and PXA-B may emit light having colors different from each other. The first pixel area PXA-R may emit a first color light, the second pixel area PXA-G may emit a second color light, and the third pixel area PXA-B may emit a third color light. For example, the first pixel area PXA-R may emit light having a first wavelength, and the second pixel area PXA-G may emit light having a second wavelength different from the first wavelength. The third pixel area PXA-B may emit light having a third wavelength different from the first and second wavelengths.

The first pixel area PXA-R may be a red pixel area, and for example may emit light having an emission wavelength of about 620 nm or more and about 700 nm or less. The second pixel area PXA-G may be a green pixel area, and for example may emit light having an emission wavelength of about 500 nm or more and about 600 nm or less. The third pixel area PXA-B may be a blue pixel area, and for example may emit light having an emission wavelength of about 410 nm or more and about 480 nm or less.

A non-pixel area NPXA is between the first pixel area PXA-R, the second pixel area PXA-G, and the third pixel area PXA-B. The non-pixel area NPXA may surround the first to third pixel areas PXA-R, PXA-G, and PXA-B. The non-pixel area NPXA may set a boundary between the first to third pixel areas PXA-R, PXA-G, and PXA-B to prevent or reduce mixing the colors together with each other between the first to third pixel areas PXA-R, PXA-G, and PXA-B.

Referring to FIG. 3, the first to third pixel areas PXA-R, PXA-G, and PXA-B may be in the same row. The first to third pixel areas PXA-R, PXA-G, and PXA-B may be the first pixel area PXA-R, the second pixel area PXA-G, and the third pixel area PXA-B, which are alternately arranged in the first direction DR1. In addition, the plurality of first pixel areas PXA-R, the plurality of second pixel areas PXA-G, and the plurality of third pixel areas PXA-B may be arranged in the second direction DR2, respectively. However, this is merely an example, and the arrangement of the first to third pixel areas PXA-R, PXA-G, and PXA-B may be variously, suitably changed. For example, the first pixel area PXA-R and the third pixel area PXA-B may be on the same row, and the second pixel area PXA-G may be in a row different from the row in which the first pixel area PXA-R and the third pixel area PXA-B are provided. FIG. 3 illustrates an arrangement of the first to third pixel areas PXA-R, PXA-G, and PXA-B as an example, but is not limited thereto and may be arranged in various suitable forms. In an embodiment, the first to third pixel areas PXA-R, PXA-G, and PXA-B may have a PENTILE® arrangement (e.g., an RGBG matrix, RGBG structure, or RGBG matrix structure) or a DIAMOND PIXEL® arrangement. PENTILE® is a duly registered trademark of Samsung Display Co., Ltd. and DIAMOND PIXEL® is a duly registered trademark of Samsung Display Co., Ltd.

In one embodiment, the first to third pixel areas PXA-R, PXA-G, and PXA-B may have the same (or substantially the same) surface area on a plane. However, the embodiment of the present disclosure is not limited thereto, and the first to third pixel areas PXA-R, PXA-G, and PXA-B may have different surface areas on the plane. For example, the first pixel area PXA-R may have the largest surface area, and the third pixel area PXA-B may have the smallest surface area.

The first to third pixel areas PXA-R, PXA-G, and PXA-B may have various suitable shapes on the plane. Although FIG. 3 illustrates the first pixel area PXA-R, the second pixel area PXA-G, and the third pixel area PXA-B, each of which has a substantially rectangular shape on the plane, the embodiment of the present disclosure is not necessarily limited thereto. Each of the first to third pixel areas PXA-R, PXA-G, and PXA-B may have a polygonal shape such as a rhombus or a pentagon, or a circular shape. In some embodiments, each of the first to third pixel areas PXA-R, PXA-G, and PXA-B may have a rectangular shape having rounded corners. In some embodiments, the first to third pixel areas PXA-R, PXA-G, and PXA-B may have different shapes on the plane.

In the display device DD (see FIG. 1) of the present disclosure, the shape, the surface area, the arrangement, etc. of the first to third pixel areas PXA-R, PXA-G, and PXA-B may be variously, suitably designed according to the colors of the emitted light or the sizes and configuration of the display device DD (see FIG. 1) and are not limited to the embodiment illustrated in FIG. 3.

Referring to FIGS. 4A-4B, each of display devices DD and DD-a according to an embodiment may include a display panel DP and an optical member PP on the display panel DP. The display panel DP may include a first base substrate BS1, a circuit layer DP-CL, and a display element layer DP-EL. The same reference numerals are used for the same components as those described in FIG. 2, and duplicated descriptions are not repeated here.

In one embodiment, the display element layer DP-EL may include light emitting elements ED and ED′. The light emitting elements ED and ED′ may include first electrodes EL1 and EL1′ on the circuit layer DP-CL, and second electrodes EL2 and EL2′ facing the first electrodes EL1 and EL1′, and an emission layer EML between the first electrodes EL1 and EL1′ and the second electrodes EL2 and EL2′, respectively. First layers HTR and ETR′ may be under the emission layer EML, for example, between the first electrodes EL1 and EL1′ and the emission layer EML, respectively. Second layers ETR and HTR′ may be above the emission layer EML, for example, between the second electrodes EL2 and EL2′ and the emission layer EML, respectively.

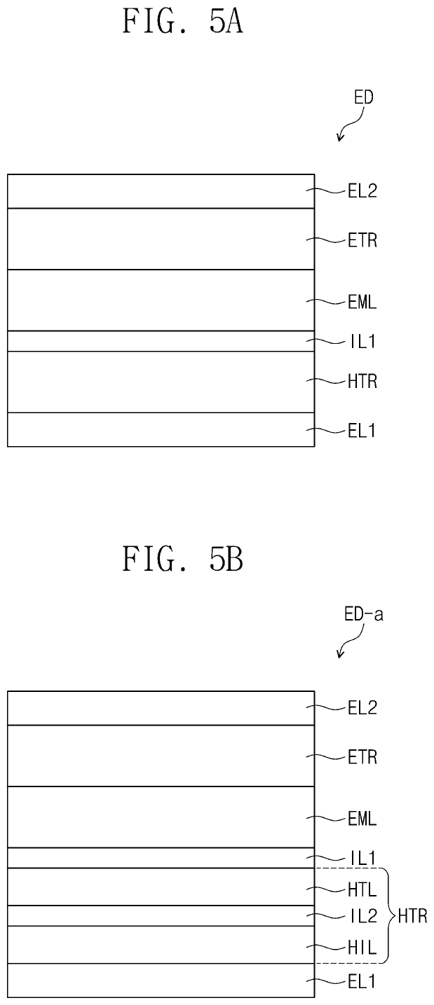

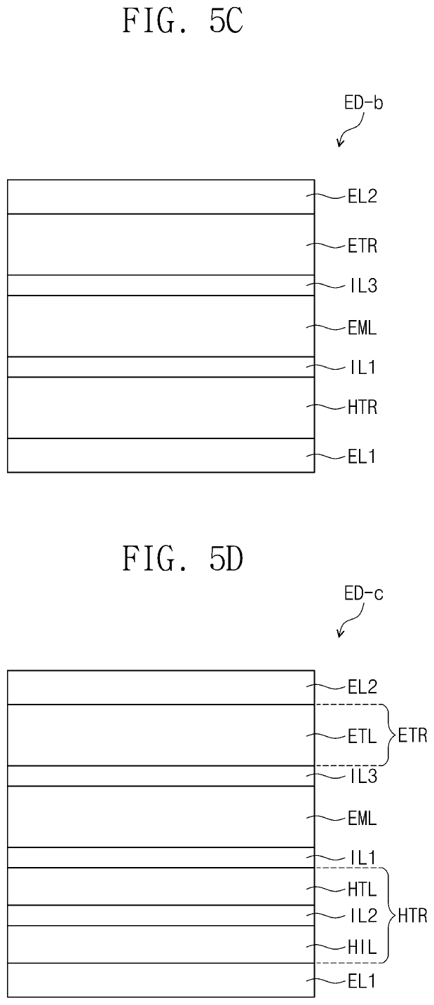

According to an embodiment of the present disclosure, first inorganic layers IL1 and IL1′ may be provided between the first layers HTR and ETR′ and the emission layer EML, respectively. When the first layers HTR and ETR′ include a plurality of layers, a second inorganic layer IL2 (see FIG. 5B) may be provided between adjacent layers of the plurality of layers. For example, the first layers HTR and ETR′ may include a plurality of sub-layers, and the second inorganic layer may be between adjacent sub-layers of the plurality of sub-layers.

The light emitting elements ED and ED′ according to an embodiment include inorganic layers on interfaces of layers between the first layers HTR and ETR′ and the emission layer EML to realize improved brightness and lifetime characteristics and excellent color reproducibility. Thus, the display devices DD and DD-a according to an embodiment may provide excellent display quality. In addition, the light emitting elements ED and ED′ according to an embodiment may further include a third inorganic layer between the emission layer EML and the second layer ETR or HTR′, respectively.

A light emitting element ED or ED′ according to an embodiment may include a structure in which a first electrode EL1 or EL1′, a first layer HTR or ETR′, an emission layer EML, a second layer ETR or HTR′, and a second electrode EL2 or EL2′ are sequentially laminated on the circuit layer DP-CL. One selected from the first layer HTR or ETR′ and the second layer ETR or HTR′ may be a hole transport region, and the other may be an electron transport region. For example, when the first layer is the hole transport region, the second layer may be an electron transport region. When the first layer is the electron transport region, the second layer may be the hole transport region.

The light emitting element ED or ED′ may be classified into a light emitting element ED having a first structure and a light emitting element ED′ having a second structure according to positions of the hole transport region and the electron transport region, which are above and below the emission layer based on the direction in which light is emitted.

Referring to FIG. 4A, the light emitting element ED having the first structure may emit light in a direction from the first electrode EL1 to the second electrode EL2. In addition, the hole transport region HTR may be below the emission layer EML, and the electron transport region ERT may be above the emission layer EML based on the direction in which the light is emitted. In the light emitting element ED having the first structure, the hole transport region HTR may correspond to the first layer, and the electron transport region ETR may correspond to the second layer.

Referring to FIG. 4B, the light emitting element ED′ having the second structure may emit light in a direction from the first electrode EL1′ to the second electrode EL2′. In addition, the light emitting element ED′ may have an inverted element structure, in which the electron transport region ETR′ is below the emission layer EML, and the hole transport region HTR′ is above the emission layer EML′ based on the direction in which the light is emitted. In the light emitting element ED′ having the second structure, the electron transport region ETR′ may correspond to the first layer, and the hole transport region HTR′ may correspond to the second layer.

First, the display element layer DP-EL including the light emitting element ED having the first structure will be described with reference to FIG. 4A.

As illustrated in FIG. 4A, the display element layer DP-EL may include a light emitting element ED having the first structure, a pixel defining layer PDL, and an encapsulation layer TFE. The light emitting element ED having the first structure may include light emitting elements ED-1, ED-2, and ED-3, which respectively correspond to the first to third pixel areas PXA-R, PXA-G, and PXA-B.

The light emitting elements ED-1, ED-2, and ED-3 may include a first light emitting element ED-1, a second light emitting element ED-2, and a third light emitting element ED-3. Each of the first to third light emitting elements ED-1, ED-2, and ED-3 may include a first electrode EL1, a hole transport region HTR, an emission layer EML, an electron transport region ETR, and a second electrode EL2, which are sequentially laminated on the circuit layer DP-CL. The first light emitting element ED-1 may overlap the first pixel area PXA-R, the second light emitting element ED-2 may overlap the second pixel area PXA-G, and the third light emitting element ED-3 may overlap the third pixel area PXA-B.

The first electrode EL1 may be on the circuit layer DP-CL. The first electrode EL1 may be provided in plurality, and the plurality of electrodes EL1 may have patterns, which are spaced apart from each other to respectively correspond to the first to third pixel areas PXA-R, PXA-G, and PXA-B. In one embodiment, each of the first electrodes EL1 may be an anode.

The pixel defining layer PDL may be on the circuit layer DP-CL. Openings OH1, OH2, and OH3 may be defined in the pixel defining layer PDL. Each of the openings OH1, OH2, and OH3 may expose at least a portion of the corresponding first electrode of the first electrodes EL1. The openings OH1, OH2, and OH3 may include a first opening OH1, a second opening OH2, and a third opening OH3. “That two structures correspond to each other” means that two structures overlap each other when viewed on the plane, but is not limited to the same surface area.

The pixel defining layer PDL includes emission areas EA1, EA2, and EA3 corresponding to the first pixel area PXA-R, the second pixel area PXA-G, and the third pixel area PXA-B. An area of the first electrodes EL1 exposed from the pixel defining layer PDL by the first opening OH1 may be defined as a first emission area EA1. An area of the first electrodes EL1 exposed from the pixel defining layer PDL by the second opening OH2 may be defined as a second emission area EA2. An area of the first electrodes EL1 exposed from the pixel defining layer PDL by the third opening OH3 may be defined as a third emission area EA3.

The first emission area EA1, the second emission area EA2, and the third emission area EA3 may be areas divided by the pixel defining layer PDL. An area between the first to third emission areas EA1, EA2, and EA3, for example, an area on which the pixel defining layer PDL is provided may be defined as the non-emission area NEA. The first emission area EA1, the second emission area EA2, and the third emission area EA3 may correspond to the first pixel area PXA-R, the second pixel area PXA-G, and the third pixel PXA-B, respectively. The emission areas EA1, EA2, and EA3 may overlap the pixel areas PXA-R, PXA-G, and PXA-B, respectively. On the plane, surface areas of the emission areas EA1, EA2, and EA3 may be the same (or substantially the same) as those of the pixel areas PXA-R, PXA-G, and PXA-B. However, the embodiment of the present disclosure is not limited thereto, and surface areas of the emission areas EA1, EA2, and EA3 may be less than those of the pixel areas PXA-R, PXA-G, and PXA-B on the plane.

In an embodiment, a top surface PDL-U of the pixel defining layer PDL may have relatively strong liquid repellency, and a side surface that is in contact with the openings OH1, OH2, and OH3 may have relatively weak liquid repellency, for example, lyophilicity. For example, during a process of injecting ink containing a light emitting material into the adjacent openings OH1, OH2, and OH3 to form the emission layer EML, the top surface PDL-U of the pixel defining layer PDL may have a relatively high contact angle for preventing or reducing mixing of the links together with each other and realizing uniform coating (e.g., substantially uniform coating). A side surface of the pixel defining layer PDL may have a relatively low contact angle to improve jetting properties of ink injected into the openings OH1, OH2, and OH3.

The hole transport region HTR may be in the first electrodes EL1. The hole transport region HTR according to an embodiment may include a deposition layer made of a hole transport material. The hole transport region HTR may include first to third hole transport regions HTR1, HTR2, and HTR3, which are respectively patterned and provided in the openings OH1, OH2, and OH3 defined in the pixel defining layer PDL. The first hole transport region HTR1 may be provided in the first opening OH1 overlapping the first emission area EA1. The second hole transport region HTR2 may be provided in the second opening OH2 overlapping the second emission area EA2. The third hole transport region HTR3 may be provided in the third opening OH3 overlapping the third emission area EA3. In some embodiments, the first to third hole transport regions HTR1, HTR2, and HTR3 may be provided in the form of a plurality of patterns spaced apart from each other on the plane.

The hole transport region HTR may include a hole transport material. According to the present disclosure, the hole transport region HTR under the emission layer EML may include at least one low molecular weight deposition layer made of a hole transport material having a molecular weight of about 10,000 g/mol or less.

A first inorganic layer IL1 may be on the hole transport region HTR. The first inorganic layer IL1 may be a thin inorganic layer. The first inorganic layer IL1 may be in direct contact with a top surface of the hole transport region HTR and a bottom surface of the emission layer EML. The first inorganic layer IL1 may include a first-1 inorganic layer IL1-1 corresponding to the first pixel area PXA-R, a first-2 inorganic layer IL1-2 corresponding to the second pixel area PXA-G, and a first-3 inorganic layer IL1-3 corresponding to the third pixel area PXA-B. The first-1 inorganic layer IL1-1 may be on the first hole transport region HTR1, the first-2 inorganic layer IL1-2 may be on the second hole transport region HTR2, and the first-3 inorganic layer IL1-3 may be on the third hole transport region HTR3.

The emission layer EML may be on the first inorganic layer IL1. The emission layer EML may be patterned using an inkjet printing method and provided in openings OH1, OH2, and OH3 defined in the pixel defining layer PDL. The emission layer EML may include a first emission layer EML-R in the first opening OH1, a second emission layer EML-G in the second opening OH2, and a third emission layer EML-R in the third opening OH3. The first emission layer EML-R may overlap the first pixel area PXA-R and may be on the first-1 inorganic layer IL1-1. The second emission layer EML-G may overlap the second pixel area PXA-G and may be on the first-2 inorganic layer IL1-2. The third emission layer EML-B may overlap the third pixel area PXA-B and may be on the first-3 inorganic layers IL1-3.

The first to third emission layers EML-R, EML-G, and EML-B may include organic light-emitting materials or quantum dots as light-emitting materials. The first emission layer EML-R may include a light emitting material that emits a third color light, the second emission layer EML-G may include a light emitting material that emits a second color light, and the third emission layer EML-B may include a light emitting material that emits a first color light.

FIG. 4A illustrates an example in which the first to third emission layers EML-R, EML-G, and EML-B include quantum dots QD1, QD2, and QD3 as light emitting materials. The quantum dots QD1, QD2, and QD3 may include a first quantum dot QD1, a second quantum dot QD2, and a third quantum dot QD3, respectively.

The first emission layer EML-R may include the first quantum dots QD1. The first quantum dot QD1 may emit red light that is the first color light. The second emission layer EML-G may include the second quantum dots QD2. The second quantum dot QD2 may emit green light that is the second color light. The third emission layer EML-B may include the third quantum dots QD3. The third quantum dot QD3 may emit blue light that is the third color light.

In an embodiment, the first color light may be light having a central wavelength in a wavelength range of about 620 nm to about 700 nm, the second color light may be light having a central wavelength in a wavelength range of about 500 nm to about 600 nm, and the third color light may be light having a central wavelength in a wavelength range of about 410 nm to about 480 nm.

The quantum dots QD1, QD2, and QD3 included in the emission layer according to an embodiment may be a semiconductor nanocrystal selected from Group II-VI compounds, Group III-VI compounds, Group I-III-VI compounds, Group III-V compounds, Group III-II-V compounds, Group IV-VI compounds, Group IV elements, Group IV compounds, and a combination thereof.

The Group II-VI compounds may be selected from binary element compounds selected from the group consisting of CdSe, CdTe, CdS, ZnS, ZnSe, ZnTe, ZnO, HgS, HgSe, HgTe, MgSe, MgS, and a combination thereof, ternary element compounds selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a combination thereof, and quaternary element compounds selected from the group consisting of CdZnSeS, CdZnSeTe, CdZnSTe, CdHgSeS, CdHgSeTe, CdHgSTe, HgZnSeS, HgZnSeTe, HgZnSTe, and a combination thereof.

The Group III-VI compounds may include binary compounds such as In₂S₃ and/or In₂Se₃; ternary compounds such as InGaS₃ and/or InGaSe₃; or any combination thereof.

The Group I-III-VI compounds may be selected from ternary compounds selected from the group consisting of AgInS, AgInS₂, CuInS, CuInS₂, AgGaS₂, CuGaS₂ CuGaO₂, AgGaO₂, AgAlO₂ and mixtures thereof and/or quaternary compounds such as AgInGaS₂ and/or CuInGaS₂.

The Group III-V compounds may be selected from binary element compounds selected from the group consisting of GaN, GaP, GaAs, GaSb, AlN, AlP, AlAs, AlSb, InN, InP, InAs, InSb, and a combination thereof, ternary element compounds selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a combination thereof, and quaternary element compounds selected form the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a combination thereof. The Group III-V compounds may further include a Group II metal. For example, InZnP and/or the like may be selected as the group III-II-V compounds.

The Group IV-VI compounds may be selected from binary element compounds selected from the group consisting of SnS, SnSe, SnTe, PbS, PbSe, PbTe, and a combination thereof, ternary element compounds selected from the group consisting of SnSeS, SnSeTe, SnSTe, PbSeS, PbSeTe, PbSTe, SnPbS, SnPbSe, SnPbTe, and a combination thereof, and quaternary element compounds selected form the group consisting of SnPbSSe, SnPbSeTe, SnPbSTe, and a combination thereof. The Group IV elements may be selected from the group consisting of Si, Ge, and a combination thereof. The Group IV compounds may be binary element compounds selected from the group consisting of SiC, SiGe, and a combination thereof.

Here, the binary element compounds, the ternary element compounds, and the quaternary element compounds may exist in the particle at a uniform concentration or exist in the particle in a state in which concentration distribution is partitioned into partially different states. In some embodiments, the quantum dot may have a core/shell structure in which one quantum dot surrounds the other quantum dot. A core/shell structure may have a concentration gradient in which an element existing in the shell has a concentration that gradually decreases along a direction toward the core.

In some embodiments, the quantum dots QD1, QD2, and QD3 may have a core-shell structure including a core including the foregoing nanocrystal and a shell surrounding the core. The shell of the quantum dots QD1, QD2, and QD3 may serve as a protective layer that prevents or reduces chemical changes to the core to maintain the semiconductor characteristics and/or may serve as a charging layer for imparting electrophoretic characteristics to the quantum dot. The shell may be a single layer or a multi-layer. Examples of the shell of the quantum dots QD1, QD2, and QD3 include metal and/or non-metal oxides, semiconductor compounds, or a combination thereof.

For example, the oxide of the metal or nonmetal may include binary element compounds of SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or the like and/or ternary element compounds MgAl₂O₄, CoFe₂O₄, NiFe₂O₄, CoMn₂O₄, and/or the like, but the embodiment of the present disclosure is not limited thereto.

In some embodiments, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but the embodiment of the present disclosure is not limited thereto.

Each of the quantum dots QD1, QD2, and QD3 may have a full width of half maximum (FWHM) of an emission wavelength spectrum of about 45 nm or less, about 40 nm or less, or, for example, about 30 nm or less. In this range, color purity and color reproducibility may be improved. Also, light emitted through the quantum dots QD1, QD2, and QD3 may be emitted in all (e.g., substantially all) directions to improve an optical viewing angle.

Also, each of the quantum dots QD1, QD2, and QD3 may have any suitable shape that is generally used in the art and is not specifically limited in shape. However, the quantum dot may have a spherical shape, a pyramidal shape, a multi-arm shape, a cubic nanoparticle shape, a nanotube shape, a nanoline shape, a nanofiber shape, a nanoplate particle shape, and/or the like.

The quantum dots QD1, QD2, and QD3 may control the color of light emitted according to the particle size, and thus, the quantum dots QD1, QD2, and QD3 may have various suitable luminous colors such as blue, red, or green.

As the particle size of each of the quantum dots QD1, QD2, and QD3 decreases, light having a short wavelength area may be emitted. For example, a particle size of the quantum dot that emits the green light from the quantum dots QD1, QD2, and QD3 having the same core may be less than that of the quantum dot that emits the red light. In addition, a particle size of the quantum dot that emits the blue light from the quantum dots QD1, QD2, and QD3 having the same core may be less than that of the quantum dot that emits the green light. However, the embodiment is not limited thereto, and even in the quantum dots QD1, QD2, and QD3 having the same core, the particle size may be adjusted according to the material for forming the shell and the thickness of the shell.

When the quantum dots QD1, QD2, and QD3 have various suitable luminous colors such as blue, red, or green, the quantum dots QD1, QD2, and QD3 having different luminous colors may have different core materials.

An electron transport region ETR may be on the emission layer EML. The electron transport region ETR may include the first electron transport region ETR1 on the first emission layer EML-R to overlap the first pixel area PXA-R, the second electron transport region ETR2 on the second emission layer EML-G to overlap the second pixel area PXA-G, and the third electron transport region ETR3 on the third emission layer EML-B to overlap the third pixel area PXA-B.

The first to third electron transport regions ETR1, ETR2, and ETR3 may be provided in common with the emission areas EA1, EA2, and EA3 and the non-emission area NEA. For example, a portion of each of the first to third electron transport regions ETR1, ETR2, and ETR3 may be on the pixel defining layer PDL, and portions of the first to third electron transport regions ETR1, ETR2, and ETR3 on the first to third emission layers EML-R, EML-G, and EML-B may be connected to each other on the pixel defining layer PDL to form a common layer having an integrated shape. Thus, the first to third electron transport regions ETR1, ETR2, and ETR3 may form the common layer having the integral shape in the emission areas EA1, EA2, and EA3 and the non-emission area NEA.

The second electrode EL2 may be on the electron transport region HTR. The second electrode EL2 may be a common electrode The second electrode EL2 may be provided as a common layer having an integral shape on the entire area of the emission areas EA1, EA2, and EA3 and the non-emission area NEA. The second electrode EL2 may be a cathode. The second electrode may include at least one selected from Ag, Mg, Cu, Al, Pt, Pd, Au, Ni, Nd, Ir, Cr, Li, Ca, LiF, Mo, Ti, W, In, Sn, and Zn, two or more kinds of compounds selected from the above-described materials, a mixture of two or more kinds of above-described materials, and/or oxides thereof.

In some embodiments, a capping layer may be further on the second electrode EL2 of the light emitting elements ED-1, ED-2, and ED-3. The capping layer may include multiple layers or a single layer. The capping layer may be an organic layer and/or an inorganic layer. For example, when the capping layer includes the inorganic material, the inorganic material may include an alkali metal compound such as LiF, an alkaline earth metal compound such as MgF₂, SiON, SiNₓ, SiO_{y}, and/or the like. For example, when the capping layer includes the organic material, the organic material may include α-NPD, NPB, TPD, m-MTDATA, Alq₃, CuPc, N4, N4, N4′, N4′-tetra (biphenyl-4-yl) biphenyl-4,4′-diamine (TPD15), 4,4′,4″-Tris(carbazol-9-yl) triphenylamine (TCTA), and/or the like, and/or may include an epoxy resin, and/or acrylic such as methacrylate. However, this embodiment is not limited thereto.

An encapsulation layer TFE may be on the light emitting elements ED-1, ED-2, and ED-3, and the encapsulation layer TFE may be on the second electrode EL2. The encapsulation layer TFE may be directly on the second electrode EL2 and may be provided while filling the opening OH. The encapsulation layer TFE may be provided as a single layer or a laminate in which a plurality of layers are laminated. The encapsulation layer TFE includes at least one insulating layer. The encapsulation layer TFE according to an embodiment may include at least one inorganic film (hereinafter, referred to as an encapsulating inorganic film). Also, the encapsulation layer TFE according to an embodiment of the present disclosure may include at least one organic layer (hereinafter, referred to as an encapsulating organic film) and at least one encapsulating inorganic film. For example, the encapsulation layer TFE may include a multilayer structure in which a first inorganic layer, an organic layer, and a second inorganic layer are sequentially laminated.

The encapsulating inorganic film protects the light emitting elements ED-1, ED-2, and ED-3 from moisture/oxygen, and the encapsulating organic film protects the light emitting elements ED-1, ED-2, and ED-3 from foreign substances such as dust particles. The encapsulating inorganic film may include silicon nitride, silicon oxy nitride, silicon oxide, titanium oxide, and/or aluminum oxide, but is not limited thereto. The encapsulating organic film may include an acrylic compound, an epoxy compound, and/or the like. The encapsulating organic film may include an organic material capable of photopolymerization, but is not particularly limited.

In one embodiment, the optical member PP may include a second base substrate BS2 and a color filter layer CFL. The display device DD according to an embodiment may further include a color filter layer CFL on the light emitting elements ED-1, ED-2, and ED-3 of the display panel DP.

The second base substrate BS2 may be a member providing a base surface on which the color filter layer CFL and/or the like is provided. The second base substrate BS2 may be a glass substrate, a metal substrate, and/or a plastic substrate. However, the embodiment of the present disclosure is not limited thereto. For example, the second base substrate BS2 may be an inorganic layer, an organic layer, or a composite layer.

The color filter layer CFL may include a light blocking part BM and a color filter part CF. The color filter part CF may include a plurality of color filters CF-R, CF-G, and CF-B. In some embodiments, the color filter layer CFL may include a first color filter CF-R that transmits a first color light, a second color filter CF-G that transmits a second color light, and a third color filter CF-B that transmits a third color light.

Each of the color filters CF-R, CF-G, and CF-B may include a polymer photosensitive resin and a pigment and/or dye. The first color filter CR-R may include a red pigment and/or dye, the second color filter CF-G may include a green pigment and/or dye, and the third color filter CF-B may include a blue pigment and/or dye. However, the embodiment of the present disclosure is not limited thereto. For example, the third color filter CF-B may not include the pigment or dye.

The light blocking part BM may be a black matrix. The light blocking part BM may include an organic light blocking material and/or an inorganic light blocking material including a black pigment and/or dye. The light blocking part BM may prevent or reduce leakage of light from and may divide a boundary between the color filter CF-R, CF-G, and CF-B adjacent to each other.

The color filter layer CFL may further include a buffer layer BFL. For example, the buffer layer BFL may be a protective layer that protects the color filters CF-R, CF-G, and CF-B. The buffer layer BFL may be an inorganic layer including at least one selected from silicon nitride, silicon oxide, and silicon oxynitride. The buffer layer BFL may be provided as a single layer or a plurality of layers.

In the embodiment illustrated in FIG. 4A, the third color filter CF-B of the color filter layer CFL may partially overlap the first color filter CF-R and the second color filter CF-G and entirely overlap the non-pixel area, but the embodiment of the present disclosure is not limited thereto. For example, the first to third color filters CF-R, CF-G, and CF-B may be separated by the light blocking part BM so as not to overlap each other. In an embodiment, each of the first to third color filters CF-R, CF-G, and CF-B may correspond to the first to third pixel areas PXA-R, PXA-G, and PXA-B. According to another embodiment, the color filter layer CFL may be omitted.

FIG. 4A illustrates an example of the optical member PP including the color filter layer CFL, and according to another embodiment, the optical member PP may include a polarization layer. The polarization layer may block or reduce provision of external light to the display panel DP from the outside. Also, the polarization layer may reduce reflected light generated from the display panel DP by external light.

The polarization layer may be a circular polarizer having an antireflection function and/or may include a linear polarizer and a λ/4 phase retarder. The polarization layer may be on the second base substrate BS2 and exposed, or the polarization layer may be below the second base substrate BS2.

Referring to FIG. 4B, a display device DD-a according to an embodiment may include a light emitting element ED′ having a second structure. The light emitting element ED′ having the second structure may include light emitting elements ED-1′, ED-2′, and ED-3′ corresponding to the first to third pixel areas PXA-R, PXA-G, and PXA-B, respectively. The light emitting elements ED-1′, ED-2′, and ED-3′ are the first light emitting element ED-1′ corresponding to the first pixel area PXA-R, the second light emitting element ED-2′ corresponding to the second pixel area PXA-G, and the third light emitting element ED-3′ corresponding to the third pixel area PXA-B. The same/similar reference numerals are used for components identical/similar to those described in FIG. 4A, and duplicate descriptions are not repeated here.

Each of the first to third light emitting elements ED-1′, ED-2′, and ED-3′ may include a first electrode EL1′, an electron transport region ETR′, an emission layer EML, a hole transport region HTR′, and a second electrode EL2′, which are sequentially laminated on the circuit layer DP-CL. According to an embodiment of the present disclosure, the first electrode EL1′ may correspond to a cathode, and the second electrode EL2′ may correspond to an anode.

In the display device DD-a according to an embodiment, the electron transport region ETR′ may be between the first electrode EL1′ and the emission layer EML. The electron transport region ETR′ may include first to third electron transport regions ETR1′, ETR2′, and ETR3′ patterned and provided in the openings OH1, OH2, and OH3 defined in the pixel defining layer PDL, respectively. The first electron transport region ETR1′ may be provided in the first opening OH1 overlapping the first emission area EA1. The second electron transport region ETR2′ may be provided in the second opening OH2 overlapping the second emission area EA2. The third electron transport region ETR3′ may be provided in the third opening OH3 overlapping the third emission area EA3. In some embodiments, the first to third electron transport regions ETR1′, ETR2′, and ETR3′ may be provided in the form of a plurality of patterns spaced apart from each other on the plane.

The electron transport region ETR′ may include an electron transport material. According to the present disclosure, the electron transport region ETR under the emission layer EML may include at least one low molecular weight deposition layer made of an electron transport material having a molecular weight of about 10,000 g/mol or less.

In the display device DD-a according to an embodiment, the first inorganic layer IL1′ may be between the electron transport region ETR′ and the emission layer EML. The first inorganic layer IL1′ may be a thin inorganic layer. The first inorganic layer IL1′ may be in direct contact with a top surface of the electron transport region ETR′ and a bottom surface of the emission layer EML. The first inorganic layer IL1′ may include a first-1 inorganic layer IL1-1′ corresponding to the first pixel area PXA-R, a first-2 inorganic layer IL1-2′ corresponding to the second pixel area PXA-G, and a first-3 inorganic layer IL1-3′ corresponding to the third pixel area PXA-B. The first-1 inorganic layer IL1-1′ may be on a first electron transport region ETR1′, the first-2 inorganic layer IL1-2′ may be on the second electron transport region ETR2′, and the first-3 inorganic layer IL1-3′ may be on the third electron transport region ETR3′.

In an embodiment, the first inorganic layer IL1′ may have a thickness and an inorganic material for preventing or reducing damage to the electron transport region ETR′ including the low molecular weight deposition layer during the formation process of the emission layer EML without (or substantially without) inhibiting charge mobility of the electron transport region ETR′. The first inorganic layer IL1′ included in the light emitting element ED′ having the second structure may have substantially the same thickness and inorganic material as the first inorganic layer IL included in the light emitting element ED having the first structure.

The emission layer EML may be provided on the first inorganic layer IL1′. The emission layer EML may be directly on the first inorganic layer IL1′. The emission layer EML included in the light emitting element ED′ having the second structure may be substantially the same as the emission layer EML included in the light emitting element ED having the first structure described with reference to FIG. 4A.

The hole transport region HTR′ may be between the emission layer EML and the second electrode EL2′. The hole transport region HTR′ may include the first hole transport region HTR1′ on the first emission layer EML-R to overlap the first pixel area PXA-R, the second hole transport region HTR2′ on the second emission layer EML-G to overlap the second pixel area PXA-G, and the third hole transport region HTR3′ on the third emission layer EML-B to overlap the third pixel area PXA-B.

The first to third hole transport regions HTR1′, HTR2′, and HTR3′ may be provided in common with the emission areas EA1, EA2, and EA3 and the non-emission area NEA. For example, a portion of each of the first to third hole transport regions HTR1′, HTR2′, and HTR3′ may be on the pixel defining layer PDL, and portions of the first to third hole transport regions HTR1′, HTR2′, and HTR3′ on the first to third emission layers EML-R, EML-G, and EML-B may be connected to the pixel defining layer PDL so as to be integrated with each other, thereby forming a common layer having an integrated shape. Thus, the first to third hole transport regions HTR1′, HTR2′, and HTR3′ may form the common layer having the integral shape on the entire area of the emission areas EA1, EA2, and EA3 and the non-emission area NEA.

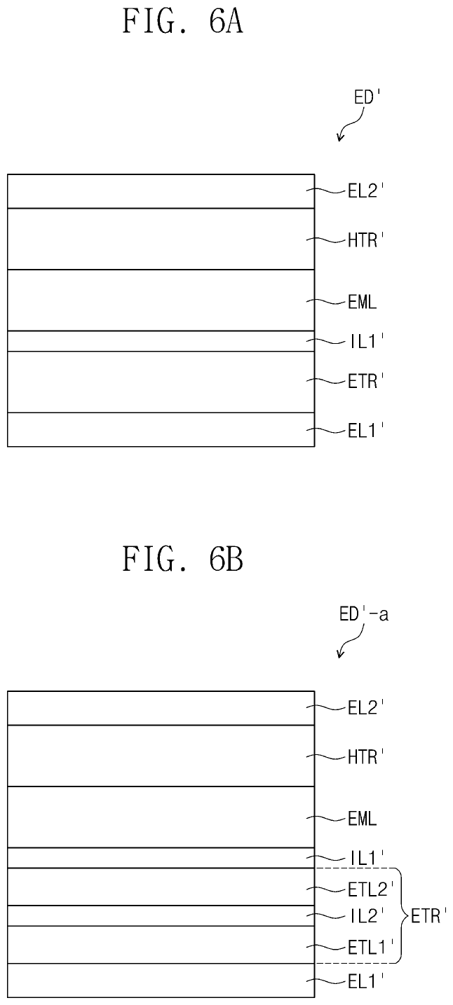

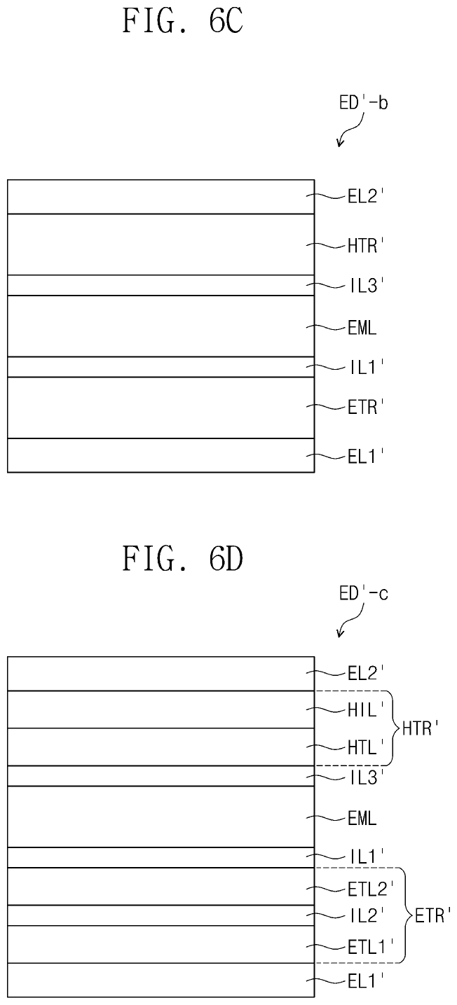

FIGS. 5A-5D and 6A-6D are schematic cross-sectional views illustrating the light emitting element according to an embodiment of the present disclosure. FIGS. 5A-5D are schematic cross-sectional views illustrating the light emitting element ED having the first structure described with reference to FIG. 4A, and FIGS. 6A-6D are schematic cross-sectional views illustrating the light emitting device ED′ having the second structure described with reference to FIG. 4B. Hereinafter, light emitting elements according to various embodiments of the present disclosure will be described with reference to FIGS. 5A-5D and 6A-6D.

Referring to FIG. 5A, the light emitting element ED according to an embodiment may include a first electrode EL1 and a second electrode EL2, which faces the first electrode EL1 and may further include a hole transport region HTR, a first inorganic layer IL1, an emission layer EML, and an electron transport region ETR between the first electrode EL1 and the second electrode EL2. The light emitting element ED according to an embodiment may have a structure in which the first electrode EL1 that is an anode, the hole transport region HTR, the first inorganic layer IL1, the emission layer EML, the electron transport region ETR, and the second electrode EL2 that is a cathode are sequentially laminated. The first inorganic layer IL1 may be directly on the hole transport region HTR.

The hole transport region HTR is provided in the first electrode EL1. The hole transport region HTR may include at least one selected from a hole injection layer, a hole transport layer, and an electron blocking layer. The hole transport region HTR may further include a buffer layer and/or an emission auxiliary layer. The electron transport region ETR may have a thickness of, for example, about 50 Å to about 15,000 Å.

The hole transport region HTR may have a single layer made of a single material, a single layer made of materials different from each other, or a multi-layered structure including a plurality of layers made of materials different from each other. When the hole transport region HTR has a multilayer structure having a plurality of layers, the hole transport region HTR may include a second inorganic layer provided between the plurality of layers.

The hole transport region HTR according to an embodiment may have a single layer or multilayer structure made of a low molecular weight material. For example, the hole transport region HTR may be made of a hole transport material having a molecular weight of about 10,000 g/mol or less. For example, the hole transport region HTR may include a single layer of a hole transport material having a molecular weight of about 10,000 g/mol or less. In this specification, the term hole transport material encompasses a hole transport material and a hole injection material. When the hole transport region HTR has a multilayer structure having a plurality of layers made of different materials, each of the plurality of layers may be a layer made of a hole transport material having a molecular weight of about 10,000 g/mol or less.

The hole transport region HTR may have a single layer structure of the hole injection layer and/or the hole transport layer and also a single layer structure made of a hole injection material and/or a hole transport material. Also, the first hole transport region HTR1 may have a single layer structure made of a plurality of different materials or a structure of the hole injection layer/hole transport layer, the hole injection layer/hole transport layer/buffer layer, the hole injection layer/buffer layer, the hole transport layer/buffer layer, or the hole injection layer/hole transport layer/electron blocking layer, which are successively laminated from the first electrode EL1, but is not limited thereto.

In one embodiment, when the hole transport region HTR includes a second inorganic layer provided between a plurality of layers, the hole transport region HTR may have a structure of hole injection layer/second inorganic layer/hole transport layer, hole injection layer/second inorganic layer/hole transport layer/second inorganic layer/buffer layer, hole injection layer/second inorganic layer/buffer layer, hole transport layer/second inorganic layer/buffer layer, or hole injection layer/second inorganic layer/hole transport layer/second inorganic layer/electron blocking layer, which are sequentially laminated from the first electrode EL1.

The hole transport region HTR may be formed by using various suitable methods such as a vacuum deposition method, a spin coating method, a casting method, a Langmuir-Blodgett (LB) method, an inject printing method, a laser printing method, and/or a laser induced thermal imaging (LITI) method. In one embodiment, the hole transport region HTR may be formed by a vacuum deposition method.

The first inorganic layer IL1 may have a thickness and an inorganic material for preventing or reducing damage to the hole transport region HTR including a deposition layer made of a low molecular weight layer during the formation process of the emission layer EML on the hole transport region HTR without (or substantially without) inhibiting charge mobility of the hole transport region HTR.

For example, the thickness of the first inorganic layer IL1 may be greater than or equal to about 10 Å and less than or equal to about 100 Å. When the thickness of the first inorganic layer IL1 is less than about 10 Å, the hole transport region HTR under the emission layer EML may be damaged by ink jetting during the process of forming the emission layer EML. In addition, when the thickness of the first inorganic layer IL1 exceeds about 100 Å, the lifetime and brightness of the light emitting element ED may decrease due to insulating properties. The first inorganic layer IL1 according to an embodiment has a thickness of about 10 Å or more and about 100 Å or less to provide smooth charge mobility and prevent or reduce damage to the first layer below the emission layer EML, e.g., the hole transport region HTR during the manufacturing process. For example, the first inorganic layer IL1 may include zinc magnesium oxide (ZnMgO).

The emission layer EML is provided on the first inorganic layer IL1. The emission layer EML may have a thickness, for example, about 100 Å to about 1,000 Å or about 100 Å to about 300 Å. The emission layer EML may have a single layer structure made of a single material, a single layer structure made of materials different from each other, or a multi-layered structure including a plurality of layers made of materials different from each other. In one embodiment, the emission layer EML may be formed by an inkjet printing method.

The electron transport region ETR may be provided on the emission layer EML and may include at least one selected from a hole blocking layer, an electron transport layer, and an electron injection layer. The electron transport region ETR may have a single layer made of a single material, a single layer made of materials different from each other, or a multi-layered structure including a plurality of layers made of materials different from each other. In this specification, the term electron transport material encompasses both electron transport materials and electron injection materials.

For example, the electron transport region ETR may have a single layer structure of the electron injection layer and/or the electron transport layer and also a single layer structure made of an electron injection material and/or an electron transport material. Also, the electron transport region ETR may have a single layer structure made of a plurality of materials different from each other or a structure of the electron transport layer/electron injection layer, the electron blocking layer/electrode transport layer/electrode injection layer, or the electron transparent layer/butter layer/electron injection layer, which are sequentially laminated from the emission layer EML, but is not limited thereto. The electron transport region ETR may have a thickness of, for example, about 1000 Å to about 1500 Å.

The electron transport region ETR may be formed by using various suitable methods such as a vacuum deposition method, a spin coating method, a casting method, a Langmuir-Blodgett (LB) method, an inject printing method, a laser printing method, and/or a laser induced thermal imaging (LITI) method. In one embodiment according to the present disclosure, the electron transport region ETR may be formed using a vacuum deposition method.

FIG. 5B is a cross-sectional view of a light emitting element ED-a according to an embodiment, in which the hole transparent region HTR includes a plurality of sub-layers HIL and HTL when compared to FIG. 5A.

Referring to FIG. 5B, the hole transport region HTR may include a hole injection layer HIL and a hole transport layer HTL, and a second inorganic layer IL2 may be between the hole injection layer HIL and the hole transport layer HTL.

In an embodiment, the hole injection layer HIL may be on the first electrode EL1, and the hole transport layer HTL may be on the hole injection layer HIL. The second inorganic layer IL2 may be between the hole injection layer HIL and the hole transport layer HTL. The second inorganic layer IL2 may be in direct contact with a top surface of the hole injection layer HIL and a bottom surface of the hole transport layer HTL.

The second inorganic layer IL2 may be a thin film inorganic layer. For example, the thickness of the second inorganic layer IL2 may be greater than or equal to about 10 Å and less than or equal to about 100 Å. The second inorganic layer IL2 may have the foregoing thickness range to provide smooth charge mobility and to prevent or reduce damage to the hole injection layer HIL during the manufacturing process. In one embodiment, the second inorganic layer IL2 may include molybdenum trioxide (MoO₃), but the embodiment is not limited thereto.

FIG. 5C is a schematic cross-sectional view illustrating a light emitting element ED-b according to an embodiment of the present disclosure. As illustrated in FIG. 5C, a third inorganic layer IL3 may be provided between the emission layer EML and the electron transport region ETR. The third inorganic layer IL3 may be in direct contact with a top surface of the emission layer EML and a bottom surface of the electron transport region ETR.

The third inorganic layer IL3 may be a thin inorganic layer. For example, the thickness of the third inorganic layer IL3 may be greater than or equal to about 10 Å and less than or equal to about 100 Å. The third inorganic layer IL3 has the foregoing thickness range and may provide smooth charge mobility. The third inorganic layer IL3 according to one embodiment may include zinc oxide (ZnO), but the embodiment of the present disclosure is not limited thereto.

FIG. 5D illustrates a cross-sectional view of a light emitting element ED-c according to an embodiment, in which the hole transport region HTR includes the hole injection layer HIL and the hole transport layer HTL, and the electron transport region ETR includes the electron transport layer ETL when compared to FIG. 5A.

The light emitting element ED-c according to an embodiment may include first to third inorganic layers IL1, IL2, and IL3. The first inorganic layer IL1 may be provided between the hole transport region HTR and the emission layer EML, and the second inorganic layer IL2 may be provided between the hole injection layer HIL and the hole transport layer HTL. The third inorganic layer IL3 may be provided between the emission layer EML and the electron transport layer ETL. The first inorganic layer IL1 may be directly on a top surface of the hole transport layer HTL and may be in contact with a bottom surface of the emission layer EML. The second inorganic layer IL2 may be directly on a top surface of the hole injection layer HIL and may be in contact with a bottom surface of the hole transport layer HTL. The third inorganic layer IL3 may be directly on a top surface of the emission layer EML and may be in contact with a bottom surface of the electron transport layer ETL.

Referring to FIG. 6A, the light emitting element ED′ according to an embodiment may include a first electrode EL1′ and a second electrode EL2′, which faces the first electrode EL1′ and may further include a hole transport region HTR′, a first inorganic layer IL1′, an emission layer EML′, and an electron transport region ETR′ between the first electrode EL1′ and the second electrode EL2′. The light emitting element ED′ may include a first electrode EL1′ that is a cathode, an electron transport region ETR′, a first inorganic layer IL1′, an emission layer EML, a hole transport region HTR′, and a second electrode EL2′ that is a anode, which are sequentially laminated. The first inorganic layer IL1′ may be directly on the electron transport region ETR′.

The electron transport region ETR′ is provided on the first electrode EL1′. The electron transport region ETR′ may include at least one selected from a hole blocking layer, an electron transport layer, and an electron injection layer, but is not limited thereto. The electron transport region ETR′ may have a single layer made of a single material, a single layer made of materials different from each other, or a multi-layered structure including a plurality of layers made of materials different from each other. When the electron transport region ETR′ has a multilayer structure having a plurality of layers, the electron transport region ETR′ may include a second inorganic layer provided between the plurality of layers.

The electron transport region ETR′ according to an embodiment may have a single layer or multilayer structure made of a low molecular weight material. For example, the electron transport region ETR′ may be made of an electron transport material having a molecular weight of about 10,000 g/mol or less. For example, the electron transport region ETR′ may include a single layer made of an electron transport material having a molecular weight of about 10,000 g/mol or less. When the electron transport region ETR′ has a multilayer structure having a plurality of layers made of different materials, each of the plurality of layers may be a layer made of an electron transport material having a molecular weight of about 10,000 g/mol or less.

The electron transport region ETR′ may have a single layer structure of the electron injection layer or the electron transport layer and also a single layer structure made of an electron injection material or an electron transport material. In addition, the electron transport region ETR′ may have a single layer structure made of a plurality of materials different from each other or a structure of the electron injection layer/electron transparent layer, the electron injection layer/electrode transport layer/hole blocking layer, or the electron injection layer/butter layer/electron transparent layer, which are sequentially laminated from the first electrode EL1′, but is not limited thereto. The electron transport region ETR′ according to an embodiment may include a plurality of electron transport layers sequentially laminated. The electron transport region ETR′ may have a thickness of, for example, about 1000 Å to about 1500 Å.

The electron transport region ETR′ may be formed by using various suitable methods such as a vacuum deposition method, a spin coating method, a casting method, a Langmuir-Blodgett (LB) method, an inject printing method, a laser printing method, and/or a laser induced thermal imaging (LITI) method. In an embodiment, the electron transport region ETR′ may be formed by a vacuum deposition method.

The first inorganic layer IL1′ may have a thickness and an inorganic material for preventing or reducing damage to the electron transport region ETR′ including a deposition layer made of a low molecular weight layer during the formation process of the emission layer EML on the electron transport region ETR′ without (or substantially without) inhibiting charge mobility of the electron transport region ETR′.

For example, the thickness of the first inorganic layer IL1′ may be greater than or equal to about 10 Å and less than or equal to about 100 Å. When the thickness of the first inorganic layer IL1′ is less than about 10 Å, the electron transport region ETR′ under the emission layer EML may be damaged by the inkjet printing process for forming the emission layer EML. In addition, when the thickness of the first inorganic layer IL1′ exceeds about 100 Å, the lifespan and brightness of the light emitting element ED′ may decrease due to insulating properties (e.g., electrically insulating properties). The first inorganic layer IL1′ according to an embodiment has a thickness of about 10 Å or more and about 100 Å or less to provide smooth charge mobility and prevent or reduce damage to the first layer below the emission layer EML, e.g., the electron transport region ETR′ during the manufacturing process. For example, the first inorganic layer IL1′ may include zinc magnesium oxide (ZnMgO).

The emission layer EML is provided on the first inorganic layer IL1′. The emission layer EML may have a thickness, for example, about 100 Å to about 1,000 Å or about 100 Å to about 300 Å. The emission layer EML may have a single layer structure made of a single material, a single layer structure made of materials different from each other, or a multi-layered structure including a plurality of layers made of materials different from each other. In one embodiment, the emission layer EML may be formed by an inkjet printing method.

The hole transport region HTR′ may have a single layer made of a single material, a single layer made of materials different from each other, or a multi-layered structure including a plurality of layers made of materials different from each other. The hole transport region HTR′ may have a thickness of, for example, about 50 Å to about 15,000 Å.

For example, the hole transport region HTR′ may have a single layer structure of the hole injection layer and/or the hole transport layer and also a single layer structure made of a hole injection material and/or a hole transport material. In addition, the hole transport region HTR′ may have a single layer structure made of a plurality of different materials, or a structure of the hole transport layer/hole injection layer, buffer layer/hole transport layer/hole injection layer, buffer layer/hole injection layer, buffer layer/hole transport layer, or electron blocking layer/hole transport layer/hole injection layer, which are sequentially stacked from the emission layer EML, but is not limited thereto.

The hole transport region HTR′ may be formed by using various suitable methods such as a vacuum deposition method, a spin coating method, a casting method, a Langmuir-Blodgett (LB) method, an inject printing method, a laser printing method, and/or a laser induced thermal imaging (LITI) method. In one embodiment according to the present disclosure, the hole transport region HTR′ may be formed using an inkjet printing method and/or a vacuum deposition method.

FIG. 6B is a cross-sectional view illustrating a light emitting element ED′-a according to an embodiment, in which the electron transport region ETR′ includes a plurality of sub-layers ETL1′ and ETL2′ when compared to FIG. 6A.

Referring to FIG. 6B, the electron transport region ETR′ may include a first electron transport layer ETL1′ and a second electron transport layer ETL2′ and may further include a second inorganic layer IL2′ between the electron transport layer ETL1′ and the second electron transport layer ETL2′.

Referring to FIG. 6B, the first electron transport layer ETL1′ may be on the first electrode EL1′, and the second electron transport layer ETL2′ may be on the first electron transport layer ETL1′. The second inorganic layer IL2′ may be on the first electron transport layer ETL1′. The second inorganic layer IL2′ may be in direct contact with a top surface of the first electron transport layer ETL1′ and may be in direct contact with a bottom surface of the second electron transport layer ETL2′.

The second inorganic layer IL2′ may be a thin inorganic layer. For example, the second inorganic layer IL2′ may have a thickness of about 10 Å or more and about 100 Å or less. The second inorganic layer IL2′ has the foregoing thickness range to provide smooth charge mobility and to prevent or reduce damage to the first electron transport layer ETL1′ during the manufacturing process. The second inorganic layer IL2′ according to one embodiment may include zinc oxide (ZnO), but the embodiment is not limited thereto.

FIG. 6C is a schematic cross-sectional view illustrating a light emitting element ED′-b according to an embodiment of the present disclosure. As illustrated in FIG. 6C, a third inorganic layer IL3′ may be provided between the emission layer EML and the hole transport region HTR′. The third inorganic layer IL3′ may be in direct contact with a top surface of the emission layer EML and a bottom surface of the hole transport region HTR′.

The third inorganic layer IL3′ may be a thin inorganic layer. For example, the thickness of the third inorganic layer IL3′ may be greater than or equal to about 10 Å and less than or equal to about 100 Å. The third inorganic layer IL3′ has the foregoing thickness range and may provide smooth charge mobility. In one embodiment, the third inorganic layer IL3′ may include molybdenum trioxide (MoO₃), but the embodiment is not limited thereto.

FIG. 6D is a cross-sectional view illustrating a light emitting element ED′-c according to an embodiment, in which the electron transport region ETR′ includes the first electron transport layer ETL1′ and the second electron transport layer ETL2′, and the hole transport region HTR′ includes the hole transport layer HTL′ and the hole injection layer HIL′.

The light emitting element ED′-c according to an embodiment may include first to third inorganic layers IL1′, IL2′, and IL3′. The first inorganic layer IL1′ may be provided between the electron transport region ETR′ and the emission layer EML, and the second inorganic layer IL2′ may be provided between the first electron transport layer ETL1′ and the second electron transport layer ETL2′. The third inorganic layer IL3′ may be provided between the emission layer EML and the hole transport layer HTL′. The first inorganic layer IL1′ may be directly on a top surface of the second electron transport layer ETL2′ of the electron transport region ETR′ and may be in contact with a bottom surface of the emission layer EML. The second inorganic layer IL2′ may be directly on a top surface of the first electron transport layer ETL1′ and may be in contact with the second electron transport layer ETL2′. The third inorganic layer IL3′ may be directly on a top surface of the emission layer EML and may be in contact with a bottom surface of the hole transport layer HTL′.

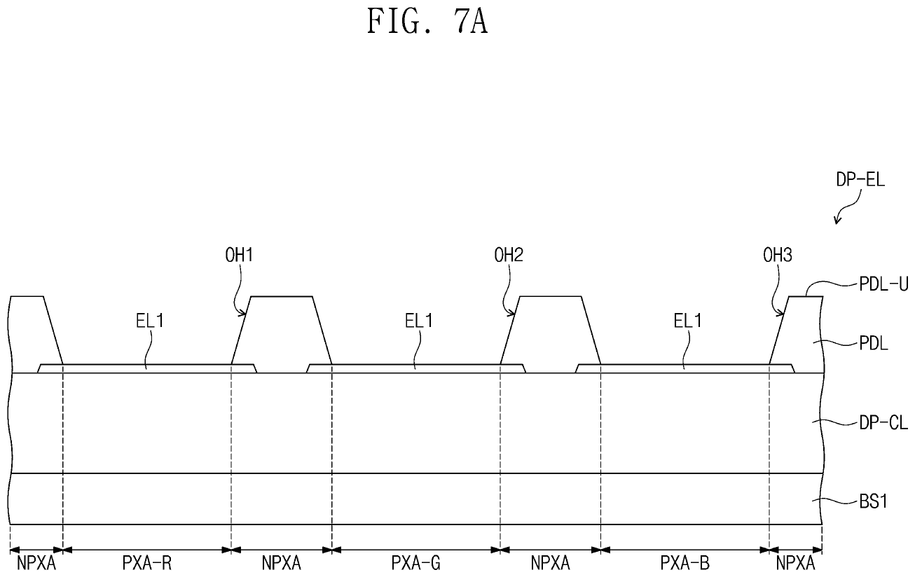

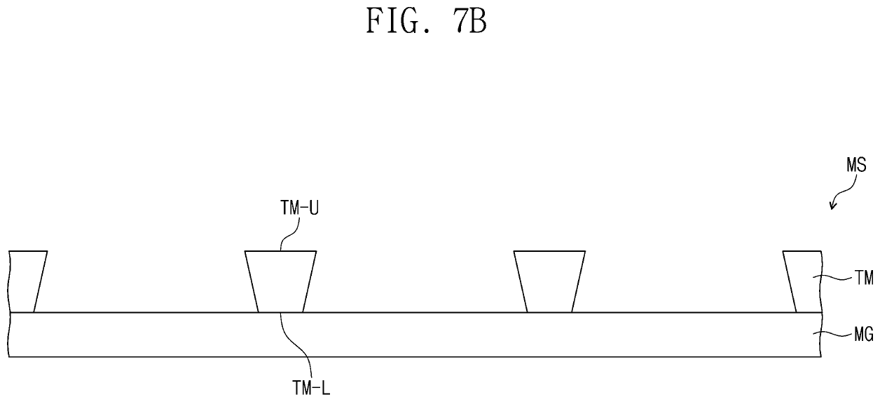

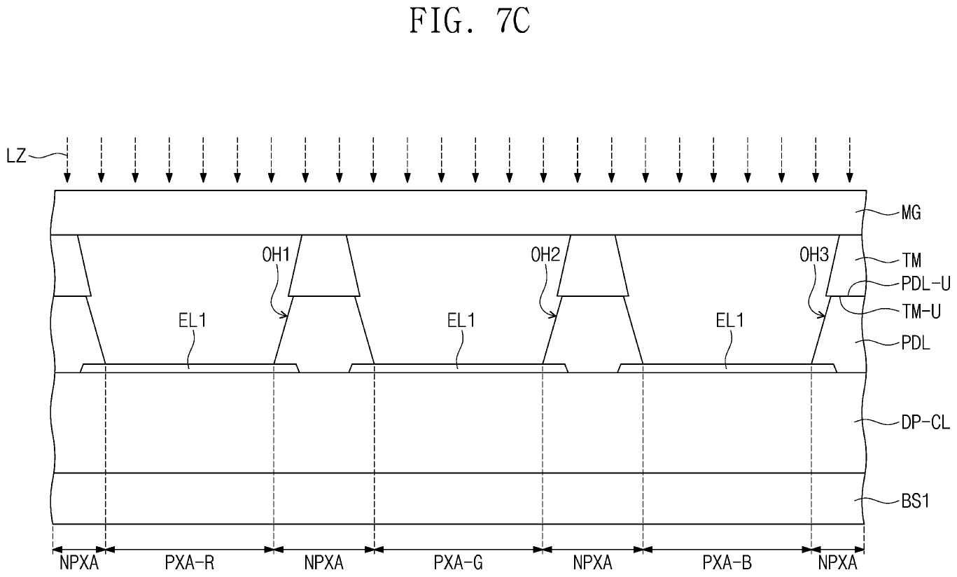

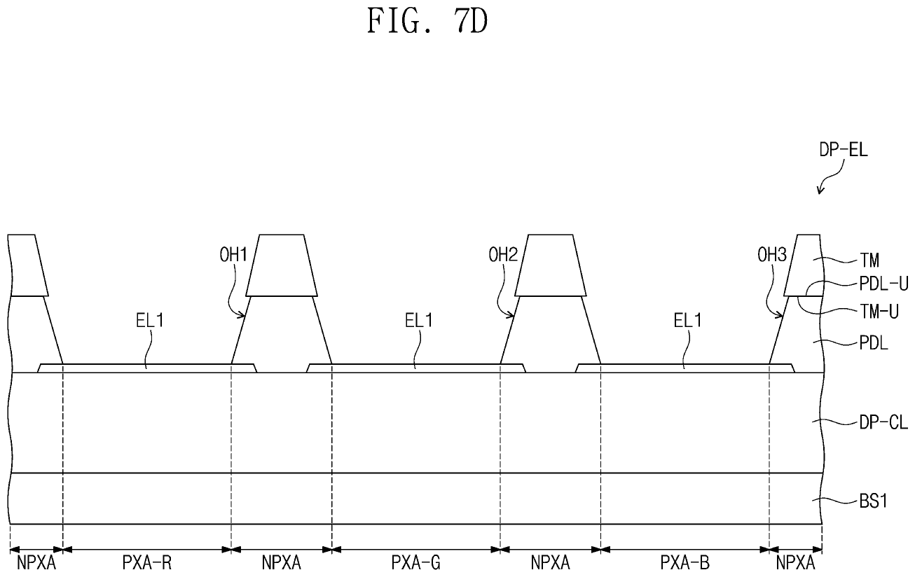

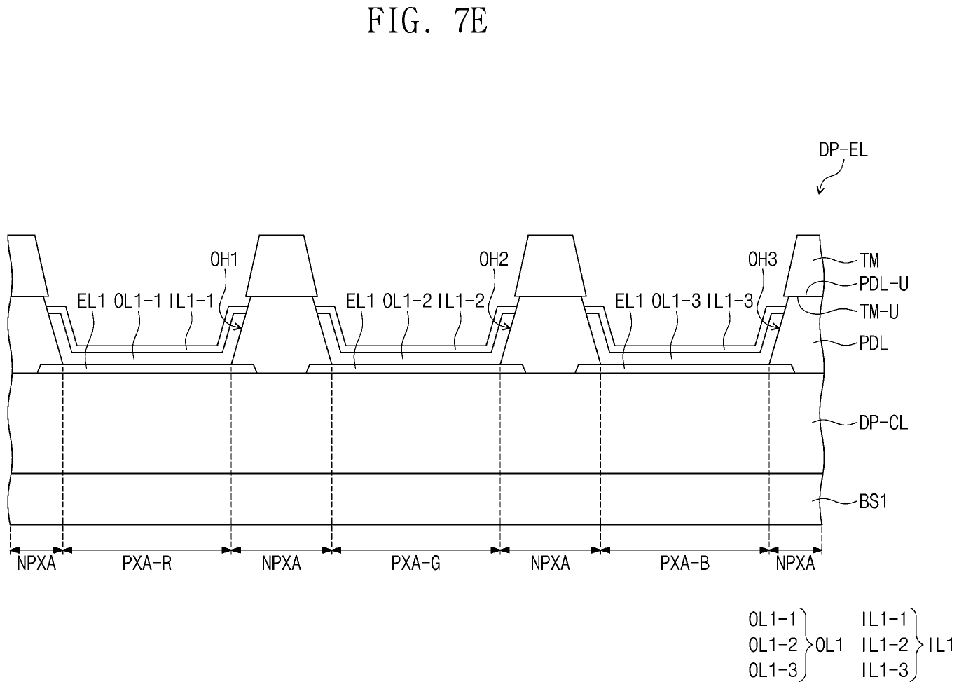

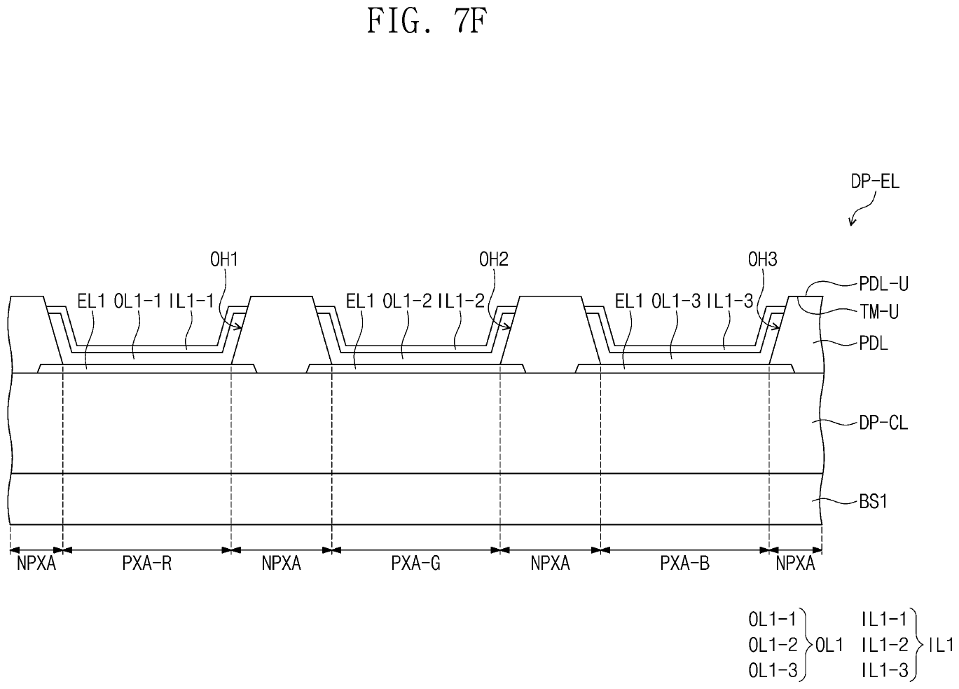

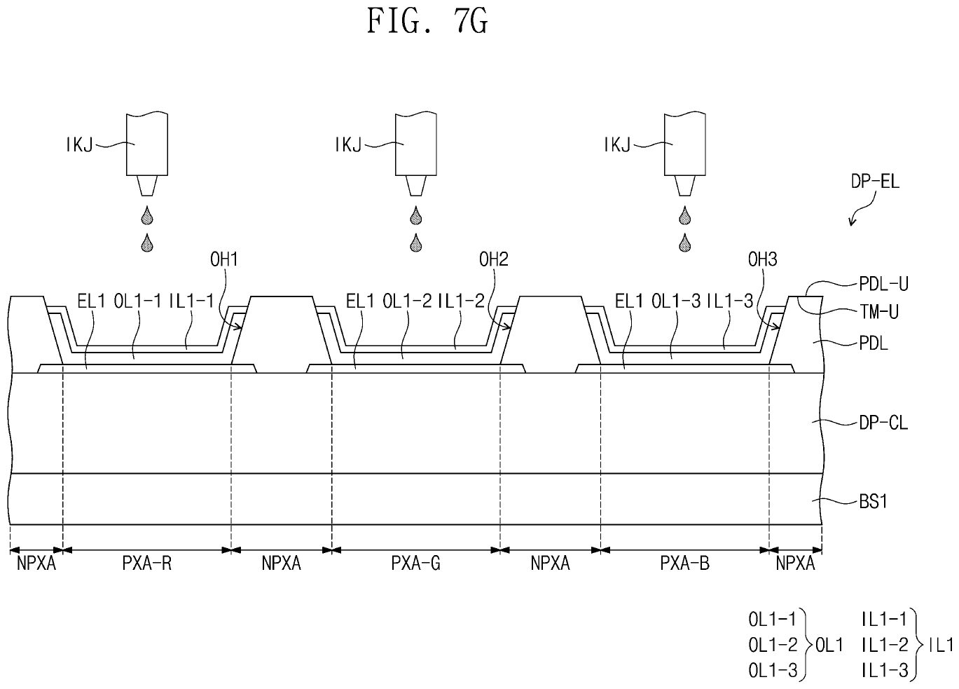

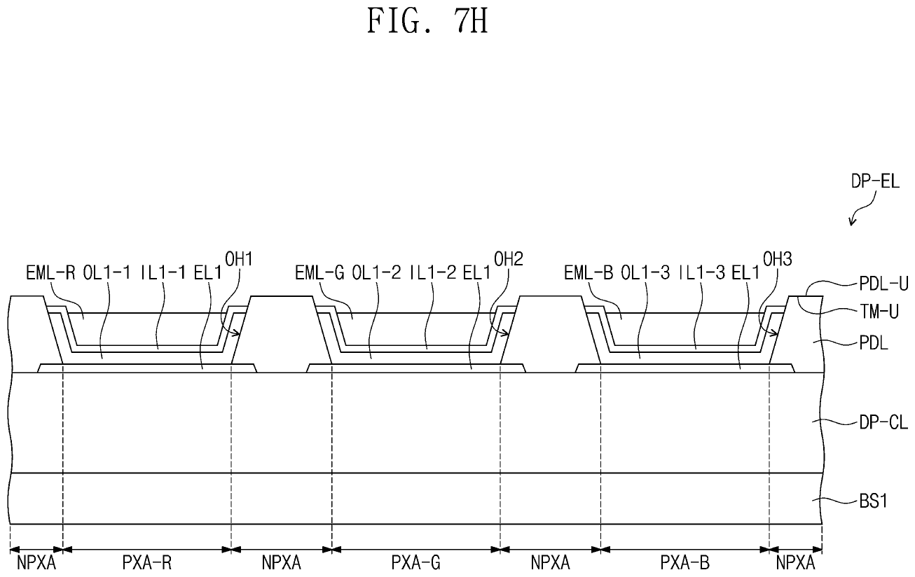

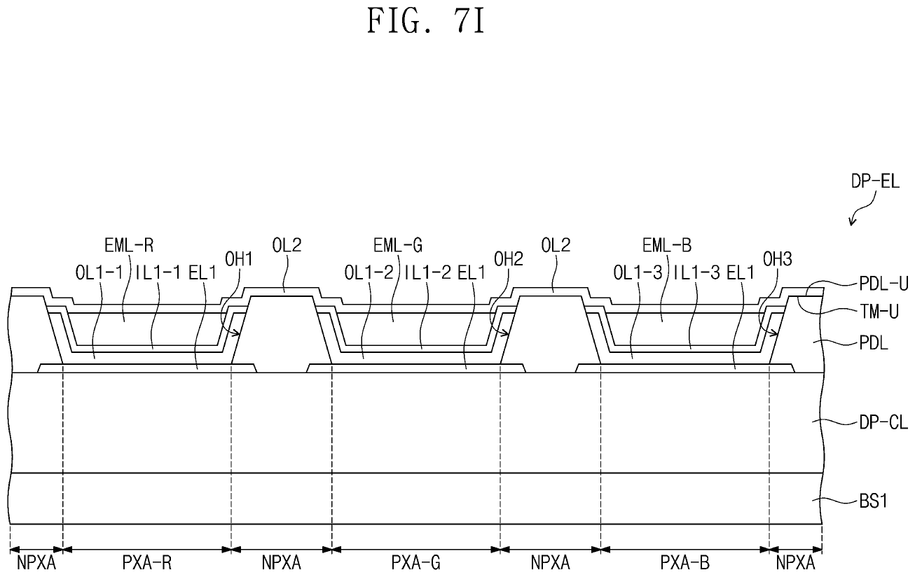

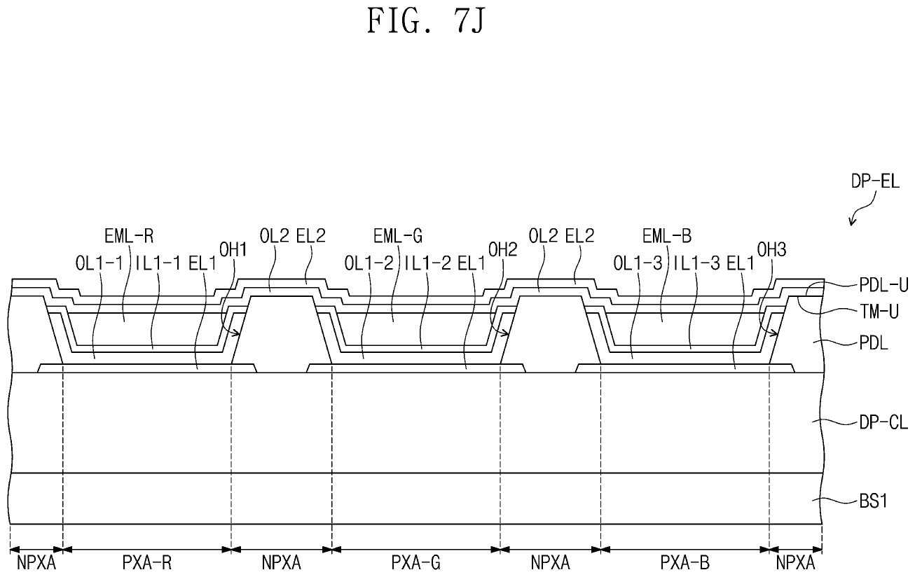

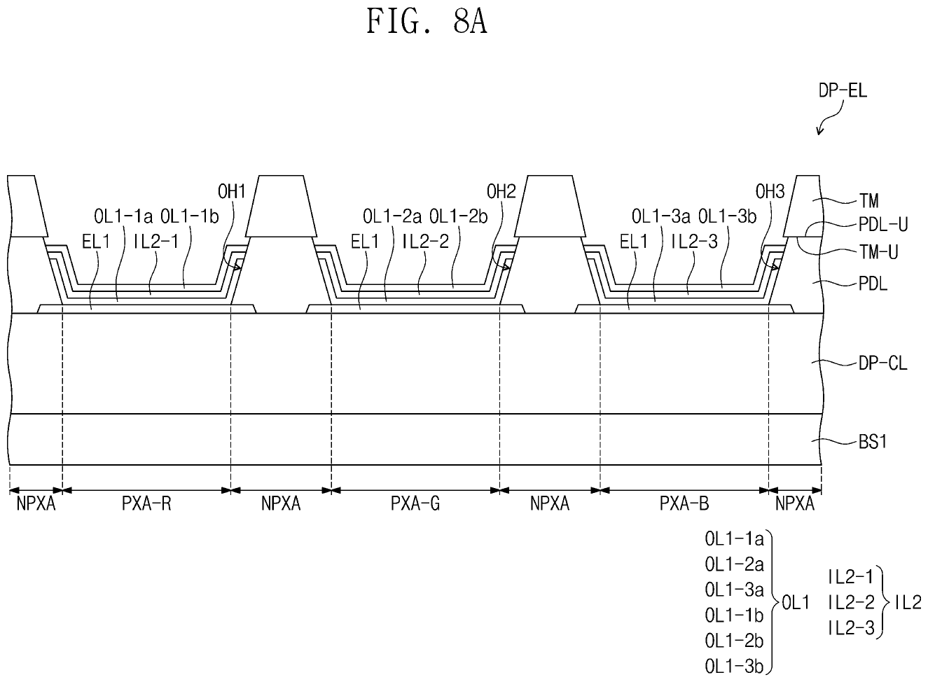

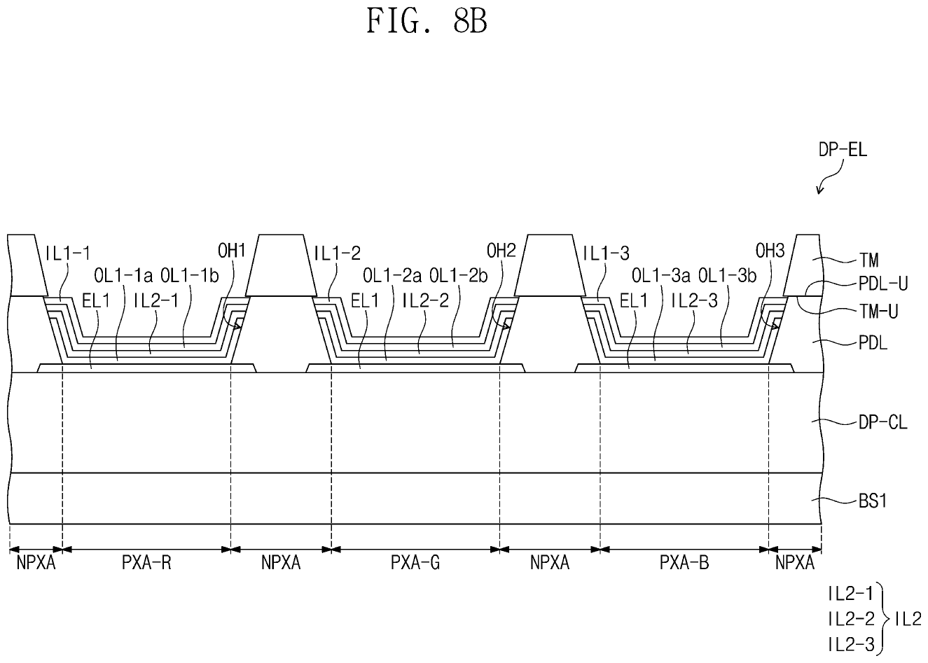

Hereinafter, a method for manufacturing the display device according to an embodiment will be described with reference to FIGS. 7A-7J, 8A-8B. FIGS. 7A-7J and 8A-8B are cross-sectional views for explaining the method for manufacturing the display device according to an embodiment of the present disclosure. Hereinafter, detailed descriptions of the constituents described with reference to FIGS. 1-6D will not be repeated.

Referring to FIG. 7A, the method for manufacturing the display device according to an embodiment may include a process of providing a preliminary substrate on which a first electrode EL1 and a pixel defining layer PDL are provided.

In an embodiment, the preliminary substrate may include a first base substrate BS1, a circuit layer DP-CL on the first base substrate BS1, first electrodes EL1 on the circuit layer DP-CL, and a pixel defining layer PDL which is on the circuit layer DP-CL and in which first to third openings OH1, OH2, and OH3 that expose at least a portion of the corresponding first electrode of the first electrodes EL1 are defined.

For example, in the process of providing the preliminary substrate, the first electrode EL1 may be formed on the first base substrate BS1, and the pixel defining layer PDL may be formed on the first electrode EL1. Thereafter, a portion of the first electrode EL1 may be exposed by forming the openings OH1, OH2, and OH3 at positions overlapping the first electrode EL1. In one embodiment, the first electrodes EL1 may be an anode or a cathode. The first electrodes EL1 and the pixel defining layer PDL may be formed through a photolithography process.

In an embodiment, the pixel defining layer PDL may be formed using a composition having a relatively stronger liquid repellency on a top surface PDL-U than on a side surface that is in contact with the openings OH1, OH2, and OH3. Thus, it is possible to prevent or reduce mixing of inks in a process of forming an emission layer to be further described herein below.

First to third pixel areas PXA-R, PXA-G, and PXA-B may be defined on the preliminary substrate. The first to third pixel areas PXA-R, PXA-G, and PXA-B may be areas corresponding to areas exposed from the pixel defining layer PDL by the first to third openings OH1, OH2, and OH3 among the first to third pixel areas PXA-R, PXA-G, and PXA-B, e.g., emission areas EA1, EA2, and EA3 (see FIG. 4A).

Referring to FIG. 7B, a method for manufacturing the display device according to an embodiment may include a process of preparing a master substrate. Referring to FIGS. 7A-7B together, the master substrate MS may include a first substrate MG and a transfer pattern TM on the first substrate MG and corresponding to the pixel defining layer PDL. The transfer pattern TM may be formed to be patterned on the first substrate MG so as to correspond to the pixel defining layer PDL illustrated in FIG. 7A. The first substrate MG may be a transparent substrate such as a glass substrate, a quartz substrate, and/or a plastic substrate.

The transfer pattern TM may include one surface TM-L that is in contact with the first substrate MG and the other surface TM-U facing the one surface TM-L. In this specification, the other surface TM-U of the transfer pattern TM may be referred to as a first surface, and the one surface TM-L of the transfer pattern TM may be referred to as a second surface.

The first surface TM-U of the transfer pattern TM may have a shape and size greater than those of the corresponding pixel defining layer PDL, or may have substantially the same shape and size as the corresponding pixel defining layer PDL. For example, when the pixel defining layer PDL has a trapezoidal shape, the transfer pattern TM may have an inverted trapezoidal shape. Also, on a plane, the first surface TM-U of the transfer pattern TM may have a surface area equal to or greater than that of the top surface PDL-U of the pixel defining layer PDL. In this specification, the meaning of “substantially the same” includes not only physically having the same numerical value, but also having slightly different numerical values within an error range that may occur in the process.

Referring to FIGS. 7C-7D, the method for manufacturing the display device according to an embodiment may include a process of transferring the transfer pattern. In the process of transferring the transfer pattern, the master substrate MS manufactured through the process described with reference to FIG. 7B is on the preliminary substrate manufactured through the process described with reference to FIG. 7A. For example, the master substrate MS may face the pixel defining layer PDL on the preliminary substrate. Here, the first surface TM-U of the transfer pattern TM may be aligned to completely overlap the top surface PDL-U of the pixel defining layer PDL.

Thereafter, the transfer pattern TM is transferred onto the pixel defining layer PDL by irradiating laser light LZ from an upper side of the master substrate MS. In one embodiment, the transfer pattern TM and the pixel defining layer PDL may adhere to each other by electrostatic attraction using an electrostatic chuck (ESC).

After the transfer pattern TM is transferred onto the pixel defining layer PDL, the first substrate MG may be removed. As a result, as illustrated in FIG. 7D, only the transfer pattern TM remains on the top surface PDL-U of the pixel defining layer PDL. In the present disclosure, the transfer pattern TM may completely cover the top surface PDL-U of the pixel defining layer PDL to prevent or reduce deterioration of the liquid repellency of the top surface PDL-U in a subsequent process.

In one embodiment, the method for manufacturing the display device may further include a preprocessing process. As illustrated in FIG. 7D, after the transfer pattern TM is transferred onto the pixel defining layer PDL, the preliminary substrate including the pixel defining layer PDL and the transfer pattern TM may be preprocessed through UV irradiation or plasma treatment to remove residues of used materials for forming the pixel defining layer PDL remaining on the openings OH1, OH2, and OH3. According to an embodiment of the present disclosure, because the top surface PDL-U of the pixel defining layer PDL is protected by the transfer pattern TM in the preprocessing process, the liquid repellency of the top surface PDL-U may be maintained. The light emitting elements ED and ED′ (see FIGS. 4A-4B) according to an embodiment may have improved lifespan characteristics and luminous efficiency as the residual materials are removed through the preprocessing process in the manufacturing process.

Referring to FIG. 7E, a process of forming a first layer OL1 and a first inorganic layer IL1 on the first electrode EL1 exposed through the openings OH1, OH2, and OH3 may be performed. The first layer OL1 and the second inorganic layer IL1 may be formed using a vacuum deposition method. However, this embodiment is not limited thereto.

First, the first layer OL1 may be formed by depositing a hole transport material and/or an electron transport material on the exposed first electrode EL1. In an embodiment, when the first electrode EL1 is an anode, the hole transport material may be deposited on the exposed first electrode EL1 to form a hole transport region HTR (see FIG. 4A). When the first electrode EL1 is a cathode, the electron transporting material may be deposited on the exposed first electrode EL1 to form an electron transporting area ETR′ (see FIG. 4B). The first layer OL1 may include first-1 to first-3 layers OL1-1, OL1-2, and OL1-3 which respectively overlap first to third pixel areas PXA-R, PXA-G, and PXA-B. When the first layer OL1 is the hole transport region HTR (see FIG. 4A), the first to third layers OL1-1, OL1-2, and OL1-3 may correspond to first to third hole transport regions HTR1, HTR2, and HTR3, respectively. When the first layer OL1 is the electron transport region ETR′ (see FIG. 4B), the first to third layers OL1-1, OL1-2, and OL1-3 may correspond to the first to third electron transport regions ETR1′, ETR2′, and ETR3′, respectively.

After forming the first layer OL1, a first inorganic layer IL1 may be formed on the first layer OL1. The first inorganic layer IL1 may include the first-1 to first-3 inorganic layers IL1-1, IL-2, and IL-3 overlapping the first to third pixel areas PXA-R, PXA-G, and PXA-B. The first-1 to first-3 inorganic layers IL1-1, IL-2, and IL-3 may cover the first-1 to first-3 layers OL1-1, OL1-2, and OL1-3. As a result, the first-1 to first-3 inorganic layers IL1-1, IL-2, and IL-3 may prevent or reduce damage to the first-1 to first-3 layers OL1-1, OL1-2, and OL1-3 in the subsequent process. The first-1 to first-3 inorganic layers IL1-1, IL-2, and IL-3 may be formed by adjusting an inorganic material according to the first layer OL1 thereunder.

Then, in the method for manufacturing the display device according to an embodiment, the transfer pattern TM may be removed as illustrated in FIG. 7F. The transfer pattern TM may be removed using a substrate coated with a material having high adhesion to the transfer pattern TM.

Referring to FIGS. 7G-7H, the method for manufacturing the display device according to an embodiment may include a process of forming the emission layer EML on the first inorganic layer IL1. The emission layer EML may be formed by an inkjet printing method. For example, referring to FIG. 7G, a soluble light emitting material may be provided into the openings OH1, OH2, and OH3 from an inkjet head IKJ. The soluble light emitting material may be patterned on the first inorganic layer IL1 in the openings OH1, OH2, and OH3 through an inkjet process. Thereafter, the emission layer EML may be formed by curing the light emitting materials on the first inorganic layer IL1. In this specification, the soluble light emitting material may be referred to as ink.

As described with reference to FIGS. 7G-7H, when the emission layer EML is formed through the inkjet process and the curing process, the emission layer EML may not include a photosensitive material. The emission layer EML may be formed without developing the photosensitive material, and because the process is performed without a photo process and an etching process, a mask may be omitted to reduce costs of forming the emission layer EML.

Referring to FIGS. 7I-7J, the method for manufacturing the display device according to an embodiment may include a process of forming a second layer OL2 and a second electrode EL2. The second layer OL2 and the second electrode EL2 may be formed as a common layer to correspond to all of the first to third pixel areas PXA-R, PXA-G, and PXA-B.

In one embodiment, the second layer OL2 may be formed using a vacuum deposition method. However, this embodiment is not limited thereto. For example, when the second layer OL2 is the hole transport region HTR′, the second layer OL2 may be formed using the vacuum deposition method and/or the inkjet printing method.

Referring to FIG. 7I, the second layer OL2 may be formed by depositing the hole transport material and/or the electron transport material on the emission layer EML. In an embodiment, when the first electrode EL1 is an anode, the electron transporting material may be deposited on the emission layer EML to form an electron transporting area ETR (see FIG. 4A). When the first electrode EL1 is a cathode, the hole transport material may be deposited on the emission layer EML to form a hole transport region HTR′ (see FIG. 4B). When the second layer OL2 includes a deposition film made of the electron transport material, the second layer OL2 may correspond to an electron transport region ETR (see FIG. 4A). When the second layer OL2 includes a deposition film made of the hole transport material, the second layer OL2 may correspond to the hole transport region HTR′ (see FIG. 4B).

In some embodiments, in the process of forming the second layer OL2, third inorganic layers IL3 and IL3′ (see FIGS. 5C-6C) may be additionally formed on the emission layer EML before forming the second layer OL2. In some embodiments, the method for manufacturing the display device according to an embodiment may further include a process of forming a third inorganic layer between the emission layer EML and the second layer OL2. The third inorganic layer may be formed using a vacuum deposition method, but is not limited thereto. An inorganic material may be selected to be used as the third inorganic layer according to the second layer OL2 formed on the emission layer EML. For example, when the second layer OL2 is the electron transport region ETR, the third inorganic layer IL3 may be a deposition layer containing ZnO. When the second layer OL2 is a hole transport region HTR′ (see FIG. 6C), the third inorganic layer IL3′ may be a deposition layer containing MoO₃.

Referring to FIG. 7J, the second electrode EL2 may be formed on the second layer OL2. The second electrode EL2 may be formed as a common layer overlapping all of the first to third pixel areas PXA-R, PXA-G, and PXA-B and the non-pixel area NPXA. In an embodiment, when the first electrode EL1 is an anode, the second electrode EL2 may be a cathode, and when the first electrode EL1 is a cathode, the second electrode EL2 may be an anode.

FIGS. 8A-8B are cross-sectional views illustrating the process of forming the first layer OL1 in the display device according to an embodiment. FIGS. 8A-8B illustrate the process of forming the first layer OL1 illustrated in FIG. 7F in more detail.

Referring to FIGS. 8A-8B, the first layer OL1 may be formed by depositing the hole transport material and/or the electron transport material on the exposed first electrode EL1. The first layer OL1 may include first sub-layers OL1-1a, OL1-2a, and OL1-3a and second sub-layers OL-1b, OL1-2b, and OL1-3b, which respectively correspond to the first to third pixel areas PXA-R, PXA-G, and PXA-B. The first inorganic layer IL1 may be formed on the second sub-layers OL-1b, OL1-2b, and OL1-3b.

In an embodiment, the second inorganic layer IL2 may be formed between the first sub-layers OL1-1a, OL1-2a, and OL1-3a and the second sub-layers OL-1b, OL1-2b, and OL1-3b. For example, the hole transport material and/or the electron transport material may be deposited on the first electrodes EL1 exposed through the openings OH1, OH2, and OH3 to form the first sub-layers OL1-1a, OL1-2a, and OL1-3a.

Thereafter, a second inorganic layer IL2 may be formed on the first sub-layers OL1-1a, OL1-2a, and OL1-3a. An inorganic material may be selected to be used for the second inorganic layer IL2 according to materials forming the first sub-layers OL1-1a, OL1-2a, and OL1-3a and the second sub-layers OL-1b, OL1-2b, and OL1-3b. For example, when the first sub-layers OL1-1a, OL1-2a, and OL1-3a and the second sub-layers OL-1b, OL1-2b, and OL1-3b are the sub-layers included in the hole transport region HTR (see FIG. 4A), each of the first sub-layers OL1-1a, OL1-2a, and OL1-3a and the second sub-layers OL-1b, OL1-2b, and OL1-3b may be deposition layers made of molybdenum oxide (MoO₃). When the first sub-layers OL1-1a, OL1-2a, and OL1-3a and the second sub-layers OL-1b, OL1-2b, and OL1-3b are the sub-layers included in the electron transport region ETR′ (see FIG. 4B), each of the first sub-layers OL1-1a, OL1-2a, and OL1-3a and the second sub-layers OL-1b, OL1-2b, and OL1-3b may be deposition layers made of zinc oxide (ZnO).

For example, when the first layer OL1 is the hole transport region HTR (see FIG. 4A), each of the first sub-layers OL1-1a, OL1-2a, and OL1-3a may be the hole injection layer HIL (see FIG. 5A). The hole injection layer HIL (see FIG. 5B) may be formed by depositing the hole injection material on the first electrodes EL1. The hole injection layer HIL (see FIG. 5B) may be the first to third hole injection layers corresponding to the first to third pixel areas PXA-R, PXA-G, and PXA-B, respectively. In addition, each of the second sub-layers OL-1b, OL1-2b, and OL1-3b may be the hole transport layer HTL (see FIG. 5B). Each of the second sub-layers OL-1b, OL1-2b, and OL1-3b may be the first to third hole transport layers on the first to third hole injection layers.

When the first layer OL1 is the electron transport region ETR′ (see FIG. 4B), each of the first sub-layers OL1-1a, OL1-2a, and OL1-3a may be the first electron transport layer ETL1′ (see FIG. 6B). The first electron transport layer ETL1′ (see FIG. 6B) may be a deposition layer deposited using the electron transport material on the first electrodes EL1. The first sub-layers OL1-1a, OL1-2a, and OL1-3a may be the first-1 to first-3 electron transport layers respectively corresponding to the first to third pixel areas PXA-R, PXA-G, and PXA-B. In addition, each of the second sub-layers

OL-1b, OL1-2b, and OL1-3b may be the second electron transport layer ETL2′ (see FIG. 6B). The second electron transport layer ETL2′ (see FIG. 6B) may be a deposition film deposited using the electron transport material on the first sub-layers OL1-1a, OL1-2a, and OL1-3a. Each of the second sub-layers OL-1b, OL1-2b, and OL1-3b may be the second-1 to second-3 electron transport layer on the first-1 to first-3 electron transport layers. The materials forming the first sub-layers OL1-1a, OL1-2a, and OL1-3a and the second sub-layers OL-1b, OL1-2b, and OL1-3b may be the same as or different from each other.

After forming the second sub-layers OL-1b, OL1-2b, and OL1-3b, as illustrated in FIG. 8B, the first inorganic layer IL1 may be formed on the second sub-layers OL-1b, OL1-2b, and OL1-3b. The first inorganic layer IL1 may be formed through the deposition process.

In the display device according to an embodiment, which is manufactured using the above-described manufacturing method, the luminance efficiency and lifespan characteristics of the light emitting element may be improved to improve the quality of the image.

According to the embodiments of the present disclosure, the inorganic layer may be provided between the emission layer and the lower layer of the emission layer to improve the luminance efficiency and the lifespan characteristics to provide the display device having the improved image quality and the method for manufacturing the same.

It will be apparent to those skilled in the art that various suitable modifications and deviations can be made to the subject matter of the present disclosure. Thus, it is intended that the present disclosure covers all modifications and deviations within the scope of the appended claims and their equivalents.

Accordingly, the technical scope of the present disclosure should not be limited to the contents described in the detailed description of the specification, but should be determined by the appended claims, and equivalents thereof.

1 what is claimed is:

1. A display device comprising:
a first base substrate on which a first pixel area configured to emit a first color light, a second pixel area configured to emit a second color light different from the first color light, and a third pixel area configured to emit a third color light different from the first color light and the second color light are defined; and
a display element layer on the first base substrate and comprising first to third light emitting elements respectively corresponding to the first to third pixel areas, wherein each of the first to third light emitting elements comprises:
a first electrode;
a first layer on the first electrode;
a first inorganic layer on the first layer;
an emission layer on the first inorganic layer;
a second layer on the emission layer; and
a second electrode on the second layer,
wherein one selected from the first layer and the second layer is a hole transport region, and the other is an electron transport region.

2. The display device of claim 1, wherein the first layer comprises a plurality of sub-layers, and
a second inorganic layer is between sub-layers adjacent to each other among the plurality of sub-layers.

3. The display device of claim 1, wherein each of the first to third light emitting elements further comprises a third inorganic layer between the emission layer and the second layer.

4. The display device of claim 1, wherein the first layer is the hole transport region comprising at least one selected from a hole injection layer, a hole transport layer, and an electron blocking layer, and
the second layer is the electron transport region comprising at least one selected from an electron injection layer, an electron transport layer, and a hole blocking layer.

5. The display device of claim 4, wherein the hole transport region comprises:
the hole injection layer on the first electrode; and
the hole transport layer on the hole injection layer,
wherein a second inorganic layer is between the hole injection layer and the hole transport layer.

6. The display device of claim 5, wherein the second inorganic layer comprises molybdenum trioxide (MoO₃).

7. The display device of claim 1, wherein the first layer is the electron transport region comprising at least one selected from an electron injection layer, an electron transport layer, and a hole blocking layer, and
the second layer is the hole transport region comprising at least one selected from a hole injection layer, a hole transport layer, and an electron blocking layer.

8. The display device of claim 7, wherein the electron transport region comprises a multilayered electron transport layer,
wherein the multilayered electron transport comprises:
a first electron transport layer on the first electrode; and
a second electron transport layer on the first electron transport layer, and
a second inorganic layer is between the first and second electron transport layer.

9. The display device of claim 8, wherein the second inorganic layer comprises zinc oxide (ZnO).

10. The display device of claim 1, wherein the first inorganic layer has a thickness of about 10 Å or more to about 100 Å or less.

11. The display device of claim 1, wherein the emission layer comprises first to third emission layers, which correspond to the first to third pixel areas, respectively, and
each of the first to third emission layers comprises a quantum dot.

12. The display device of claim 1, wherein the first layer comprises a hole transport material and/or an electron transport material having a molecular weight of about 10,000 g/mol or less.

13. The display device of claim 1, wherein the first inorganic layer comprises ZnMgO.

14. A method for manufacturing a display device, the method comprising:
providing a preliminary substrate on which a first electrode and a pixel defining layer that exposes a portion of the first electrode are provided;
preparing a master substrate on which a transfer pattern patterned to correspond to the pixel defining layer is formed;
transferring the transfer pattern onto the pixel defining layer;
forming a first layer on the exposed first electrode;
depositing a first inorganic layer on the first layer;
removing the transfer pattern;
forming an emission layer on the first inorganic layer by an inkjet printing method;
forming a second layer on the emission layer; and
forming a second electrode on the second layer,
wherein the forming of the first layer comprises forming a deposition layer made of a hole transport material and/or an electron transport material.

15. The method of claim 14, wherein the forming of the second layer comprises:
forming a third inorganic layer on the emission layer; and
forming the second layer on the third inorganic layer.

16. The method of claim 14, wherein the pixel defining layer comprises a bottom surface that is in contact with a circuit layer and a top surface facing the bottom surface,
the transfer pattern comprises a first surface that is in contact with the top surface of the pixel defining layer and a second surface facing the first surface, and
on a plane, the first surface has a surface area equal to or greater than that of the top surface of the pixel defining layer.

17. The method of claim 14, wherein the forming of the first layer comprises:
depositing a hole injection material on the first electrode to form a first sub-layer;
forming a second inorganic layer on the first sub-layer; and
depositing a hole transport material on the second inorganic layer to form a second sub-layer.

18. The method of claim 17, wherein the forming of the second layer comprises depositing an electron transport material on the emission layer.

19. The method of claim 14, wherein the forming of the first layer comprises:
depositing an electron transport material on the first electrode to form a first sub-layer;
forming a second inorganic layer on the first electron transport layer; and
depositing a material that is equal to or different from the electron transport material on the second inorganic layer to form a second sub-layer.

20. The method of claim 14, further comprising, before the forming of the first layer, preprocessing the substrate.
